(19) United States
(12) Patent Application Publication
(10) Pub. No.: US 2026/0310851 A1
(43) Pub. Date: Oct. 8, 2026

(54) SYSTEMS AND METHODS FOR RESOURCE EXTRACTION

(71) Applicant: Schlumberger Technology Corporation, Sugar Land, TX (US)

(72) Inventors: Roger A. Daar, JR., Houston, TX (US); Polina Putintseva, Abingdon (GB); Sharad Dubey, Houston, TX (US); Vasudhaven Sudhakar, Houston, TX (US); Colin Bolton, Houston, TX (US)

(21) Appl. No.: 19/577,648

(22) Filed: Mar. 25, 2026

Related U.S. Application Data
(60) Provisional application No. 63/783,105, filed on Apr. 3, 2025.

(51) Int. Cl. G06F 30/20

(52) U.S. Cl. CPC G06F 30/20

(57) ABSTRACT

Systems and methods for resource extraction are provided. A method includes: receiving inputs for estimating production of a target resource from a resource extraction operation in an area of interest (AOI), the inputs comprising a recovery factor for the target resource, one or more objectives for the resource extraction, and one or more parameters of the AOI, the one or more parameters comprising one or more of: a porosity, a permeability, or a concentration of the target resource, determining a quality index (QI) for the target resource using the one or more parameters, and a recoverable amount (RA) of the target resource using the recovery factor and the one or more parameters, and identifying a highest quality region for resource recovery for the target resource as a region of interest (ROI) using the QI, the RA, and the objectives for the resource extraction.

### CROSS REFERENCE TO RELATED APPLICATIONS

This application claims priority and the benefit of U.S. patent application No. 63/783,105, filed on Apr. 3, 2025, which is hereby incorporated by reference in its entirety.

### TECHNICAL FIELD

This disclosure generally relates to systems and methods for resource extraction.

### BACKGROUND

Brine mining can be used for extraction of resources, such as lithium, uranium, bromine, oil, and gas, contained in the brine. Brines may be produced from subsurface earth formations. Wellbore drilling operations include drilling a well bore to access reservoirs of lithium and other subsurface compounds. Downhole tools may operate using drilling fluid pressure releasing different reservoir fluids from the bore. The reservoir fluids may be processed to recover resources therefrom. A static model of the reservoir is often produced during a Pre-Feasibility stage as part of planning the drilling operation to determine whether the cost and time of the proposed extraction has an acceptable value to move forward with the project.

To locate and extract the brines containing the desired resource, such as mineral salts, a model may be produced to show target locations where the concentrations of the resource are highest and/or most cost-effective to extract. Conventional methods of calculating and modelling mineral salt resources at the Pre-Feasibility phase for a brine field development project is mostly limited to static models of brine, and/or mineral salt in place multiplied by a recovery factor. Sophisticated dynamic modeling work is rarely undertaken at the Pre-Feasibility phase to confirm that a unique reservoir can supply brine at rates sufficient to meet the plant product manufacturing rate within a predefined project budget. Nor is dynamic modeling work commonly undertaken at Pre-Feasibility to ascertain what the plant product manufacturing rate and brine well count should be given a unique reservoir. Thus, project expectations are often set at Pre-Feasibility using less sophisticated static modeling work to make predictions of both total resource recovery and resource recovery rate over time.

Traditional brine mining takes place in an arid environment that enables this method to employ only brine production wells, surface piping, evaporation ponds, tools to till and dry the salt, and skips to load the salt and trucks to haul away the unprocessed dried product. This method has changed little over the previous centuries and is a time-tested, low-cost method that employs non-rigorous subsurface technical description and little to no reservoir management in practice. But with the recent addition of critical mineral development projects using direct lithium extraction under consideration, there is a need for drilling wellbores for collecting subsurface brines. Furthermore, determining the quality of the brines in different locations of the subsurface is helpful to optimize the production of the critical mineral.

Accordingly, there is a need for the desired technical assurance level as early as the Pre-Feasibility phase without having to wait for the dynamic modeling predictions derived from the later concept selection phase.

### SUMMARY

This disclosure pertains to systems and methods for resource extraction.

A first aspect of this disclosure pertains to a method, including: receiving inputs for estimating production of a target resource from a resource extraction operation in an area of interest (AOI), the inputs including a recovery factor for the target resource in the AOI, one or more objectives for the resource extraction, and one or more parameters of the AOI, the one or more parameters of the AOI including one or more of: a porosity of the AOI, a permeability of the AOI, or a concentration of the target resource in the AOI, determining a quality index (QI) for the target resource for the AOI using the one or more parameters of the AOI, and a recoverable amount (RA) of the target resource for the AOI using the recovery factor and the one or more parameters of the AOI, and identifying a highest quality region for resource recovery for the target resource as a region of interest (ROI) using the QI, the RA, and the objectives for the resource extraction.

A second aspect of this disclosure pertains to the method of the first aspect, and further includes running a static model of the AOI to determine the one or more parameters for the AOI.

A third aspect of this disclosure pertains to the method of aspects 1 or 2, wherein determining the quality index includes providing a QI grid corresponding to the AOI, the QI grid including a plurality of QI cells respectively corresponding to regions of the AOI, each of the plurality of QI cells in the QI grid having a respective QI value for the target resource.

A fourth aspect of this disclosure pertains to the method of the third aspect, wherein the determining the recoverable amount for the target resource includes providing an RA grid corresponding to the AOI, the RA grid including a plurality of RA cells respectively corresponding to the regions of the AOI and respectively to the plurality of QI cells, each of the plurality of RA cells in the RA grid having a respective RA value for the target resource.

A fifth aspect of this disclosure pertains to the method of any preceding aspect, wherein the one or more objectives for the resource extraction include a production target value for the target resource.

A sixth aspect of this disclosure pertains to the method of any of aspects 1 to 4, and further includes determining a production target value for the target resource based on the one or more objectives for the resource extraction.

A seventh aspect of this disclosure pertains to the method of the sixth aspect, wherein the one or more objectives for the resource extraction include: a desired period of time for resource extraction from the AOI, and a target periodic production rate for the target resource.

An eighth aspect of this disclosure pertains to the method of any of aspects 5 to 7, wherein the identifying a highest quality region for resource recovery for the target resource as a region of interest (ROI) includes: identifying a first QI cell having a highest QI value among the plurality of QI cells in the QI grid, identifying a first RA cell in the RA grid corresponding to the first QI cell in the QI grid, and comparing a first RA value of the first RA cell to the production target value.

A ninth aspect of this disclosure pertains to the method of the eighth aspect, and further includes, when the RA value of the first RA cell is greater than or equal to the production target value, determining that the first RA cell corresponds to the ROI.

A tenth aspect of this disclosure pertains to the method of any of aspects 8 or 9, further including, when the RA value of the first RA cell is less than the production target value: identifying a first expanded QI region in the QI grid, the first expanded QI region including: the first QI cell, and a second QI cell in contact with the first QI cell, the second QI cell having a second-highest QI value among the plurality of QI cells in the QI grid, identifying a first expanded RA region in the RA grid, the first expanded RA region including: the first RA cell, and a second RA cell in the RA grid corresponding to the second QI cell in the QI grid, adding together the RA values for all of the cells in the first expanded RA region to determine a first expanded RA region value, and comparing the first expanded RA region value to the production target value.

An eleventh aspect of this disclosure pertains to the method of the tenth aspect, and further includes, when the first expanded RA region value is greater than or equal to the production target value, determining that the first expanded RA region corresponds to the ROI.

A twelfth aspect of this disclosure pertains to the method of any of aspects 10 or 11, and further includes, when the first expanded RA region value is less than the production target value: repeating, until a next expanded RA region value is greater than or equal to the production target value: identifying a next expanded QI region in the QI grid, the next expanded QI region including: a most recent expanded QI region, and a next QI cell in contact with the most recent expanded QI region, the next QI cell having a next-highest QI value among the plurality of QI cells in the QI grid, identifying a next expanded RA region in the RA grid, the next expanded RA region including: a most recent expanded RA region, and a next RA cell in the RA grid corresponding to the next QI cell in the QI grid, adding together the RA values for all of the cells in the next expanded RA region to determine a next expanded RA region value, and comparing the next expanded RA region value to the production target value, and when the next expanded RA region value is greater than or equal to the production target value, determining that the next expanded RA region corresponds to the ROI.

A thirteenth aspect of this disclosure pertains to the method of any of aspects 5 to 12, and further includes: simulating the resource extraction operation for the identified ROI to determine a respective productivity index (PI) for each cell in the ROI, determining an average PI value for the cells in the ROI, and determining an initial number of wells to be placed in the identified ROI to meet the production target value based on the average PI value when the resource extraction operation is performed in the AOI.

A fourteenth aspect of this disclosure pertains to the method of the thirteenth aspect, wherein the simulating the resource extraction operation includes performing a dynamic simulation on one or more notional wells for each cell to derive a brine flow rate in the one or more notional wells, the dynamic simulation using the one or more parameters of the AOI.

A fifteenth aspect of this disclosure pertains to the method of the fourteenth aspect, wherein the dynamic simulation applies a linear flow rate equation for each of the notional wells.

A sixteenth aspect of this disclosure pertains to the method of the fifteenth aspect, wherein the dynamic simulation is performed for a period shorter than 100 days.

A seventeenth aspect of this disclosure pertains to the method of any preceding aspect, wherein: the target resource includes a material in a brine, the QI is a brine quality index (BQI), and the BQI is expressed as:

$$BQI = \sum ( RQI \times Vc \times \text{?} ) ,$$

$$\text{?} \text{indicates text missing or illegible when filed}$$

where: C_{T} is a concentration of the material in the brine, Sw,c is an initial water saturation in a cell, Vc is a cell volume, and RQI is a reservoir quality index.

An eighteenth aspect of this disclosure pertains to the method of the seventeenth aspect, wherein: an overall reservoir quality index (RQI) is expressed by:

$$RQI = 0.0314 \sqrt{\frac{k}{ϕ}} ,$$

where: k is a permeability, and φ is a porosity.

A nineteenth aspect of this disclosure pertains to the method of any of any of aspects 17 or 18, wherein: the target resource includes lithium, the BQI is a lithium quality index (LQI), and the LQI is expressed as:

$$LQI = \sum ( RQI \times Vc \times \text{?} ) ,$$

$$\text{?} \text{indicates text missing or illegible when filed}$$

where: C_{Li} is a lithium concentration in the brine.

A twentieth aspect of this disclosure pertains to the method of any of aspects 13 to 19, wherein the determining the initial number of wells includes: determining an average target resource concentration for the cells in the ROI, multiplying the average target resource concentration by a periodic production rate, and dividing a result of the multiplying by the average PI value for the ROI.

A twenty-first aspect of this disclosure pertains to the method of any preceding aspect, wherein the target resource includes at least one of: lithium, oil, gas, a mineral, or a brine.

A twenty-second aspect of this disclosure pertains to a method including: receiving inputs for estimating production of a target resource from a resource extraction operation in an area of interest (AOI), the inputs including one or more parameters for the AOI, including a porosity of the AOI, a permeability of the AOI, a concentration of the target resource in the AOI, one or more objectives for the resource extraction, deriving a production target value from the one or more objectives for the resource extraction, simulating the resource extraction operation in at least a region of interest (ROI) of the AOI to determine a respective productivity index (PI) for each cell in the ROI using the one or more parameters for the ROI, the simulating the resource extraction operation including performing a dynamic simulation for one or more notional wells for each cell to derive a brine flow rate in the one or more notional wells, the dynamic simulation using the one or more parameters for the ROI, determine an average PI value for the cells in the ROI, and determining an initial number of wells to be placed in the ROI to meet the production target value based on the average PI value when the resource extraction operation is performed in the AOI.

A twenty-third aspect of this disclosure pertains to the method of the twenty-third aspect, and further includes running a static model of the AOI to determine the one or more parameters for the AOI.

A twenty-fourth aspect of this disclosure pertains to the method of any of aspects 22 or 23, wherein the one or more objectives for the resource extraction include a production target value for the target resource.

A twenty-fifth aspect of this disclosure pertains to the method of any of aspects 22 or 23, wherein: the one or more objectives for the resource extraction include: a desired period of time for resource extraction from the AOI, and a target periodic production rate for the target resource, and the method further includes calculating the production target resource value based on the desired period of time for resource extraction from the AOI and the target periodic production rate for the target resource.

A twenty-sixth aspect of this disclosure pertains to the method of any of aspects 22 to 25, wherein the dynamic simulation applies a linear flow rate equation for each of the notional wells.

A twenty-seventh aspect of this disclosure pertains to the method of any of aspects 22 to 26, wherein the dynamic simulation is performed for a period shorter than 100 days.

A twenty-eighth aspect of this disclosure pertains to the method of any of aspects 22 to 27, wherein the determining the initial number of wells includes: determining an average target resource concentration for the cells in the ROI, multiplying the average target resource concentration by a periodic production rate, and dividing a result of the multiplying by the average PI value for the ROI.

A twenty-ninth aspect of this disclosure pertains to the method of any of aspects 22 to 28, wherein the target resource includes at least one of: lithium, oil, gas, a mineral, or a brine.

A thirtieth aspect of this disclosure pertains to the method of any of aspects 22 to 29, further including mapping the productivity index for the ROI based on the average PI value.

A thirty-first aspect of this disclosure pertains to the method of the thirtieth aspect, and further includes identifying which contiguous area has a highest collective productivity index.

A thirty-second aspect of this disclosure pertains to the method of the thirty-first aspect, and further includes determining an acreage of the contiguous area used in production or costs of the production based on the objectives for the target resource extraction.

A thirty-third aspect of this disclosure pertains to the method of any of aspects 22 to 32, further including: determining whether one or more rate sensitivities exist for the resource extraction, and deriving the productivity index based on the rate sensitivities.

A thirty-fourth aspect of this disclosure pertains to the method of the thirty-third aspect, wherein: the productivity index is based on a drawdown pressure, and the one or more rate sensitivities include a drawdown pressure rate sensitivity.

A thirty-fifth aspect of this disclosure pertains to the method of any of aspects 22 to 34, and further includes selecting the ROI, the selecting the ROI including: determining a quality index (QI) for the target resource for the AOI using the one or more parameters of the AOI, and a recoverable amount (RA) of the target resource for the AOI using the one or more parameters of the AOI and the recovery factor, and identifying the region of interest (ROI) using the QI and the RA and the objectives for the resource extraction.

A thirty-sixth aspect of this disclosure pertains to the method of the thirty-fifth aspect, wherein the determining the quality index includes providing a QI grid corresponding to the AOI, the QI grid including a plurality of QI cells respectively corresponding to regions of the AOI, each of the plurality of QI cells in the QI grid having a respective QI value for the target resource.

A thirty-seventh aspect of this disclosure pertains to the method of the thirty-sixth aspect, wherein the determining the recoverable amount for the target resource includes providing an RA grid corresponding to the AOI, the RA grid including a plurality of RA cells respectively corresponding to the regions of the AOI and respectively to the plurality of QI cells, each of the plurality of RA cells in the RA grid having a respective RA value for the target resource.

A thirty-eighth aspect of this disclosure pertains to the method of any of aspects 36 to 37, wherein the identifying the region of interest (ROI) includes: identifying a first QI cell having a highest QI value among the plurality of QI cells in the QI grid, identifying a first RA cell in the RA grid corresponding to the first QI cell in the QI grid, and comparing a first RA value of the first RA cell to the production target value.

A thirty-ninth aspect of this disclosure pertains to the method of the thirty-eighth aspect, and further includes, when the RA value of the first RA cell is greater than or equal to the production target value, determining that the first RA cell corresponds to the ROI.

A fortieth aspect of this disclosure pertains to the method of any of aspects 38 or 39, and further includes, when the RA value of the first RA cell is less than the production target value: identifying a first expanded QI region in the QI grid, the first expanded QI region including: the first QI cell, and a second QI cell in contact with the first QI cell, the second QI cell having a second-highest QI value among the plurality of QI cells in the QI grid, identifying a first expanded RA region in the RA grid, the first expanded RA region including: the first RA cell, and a second RA cell in the RA grid corresponding to the second QI cell in the QI grid, adding together the RA values for all of the cells in the first expanded RA region to determine a first expanded RA region value, and comparing the first expanded RA region value to the production target value.

A forty-first aspect of this disclosure pertains to the method of the fortieth aspect, and further includes, when the first expanded RA region value is greater than or equal to the production target value, determining that the first expanded RA region corresponds to the ROI.

A forty-second aspect of this disclosure pertains to the method of any of aspects 40 or 41, and further includes, when the first expanded RA region value is less than the production target value: repeating, until a next expanded RA region value is greater than or equal to the production target value: identifying a next expanded QI region in the QI grid, the next expanded QI region including: a most recent expanded QI region, and a next QI cell in contact with the most recent expanded QI region, the next QI cell having a next-highest QI value among the plurality of QI cells in the QI grid, identifying a next expanded RA region in the RA grid, the next expanded RA region including: a most recent expanded RA region, and a next RA cell in the RA grid corresponding to the next QI cell in the QI grid, adding together the RA values for all of the cells in the next expanded RA region to determine a next expanded RA region value, and comparing the next expanded RA region value to the production target value, and when the next expanded RA region value is greater than or equal to the production target value, determining that the next expanded RA region corresponds to the ROI.

A forty-third aspect of this disclosure pertains to the method of any of aspects 35 to 42, wherein: the target resource includes a material in a brine, the QI is a brine quality index (BQI), and the BQI is expressed as:

$$BQI = \sum ( RQI \times Vc \times \text{?} ) ,$$

$$\text{?} \text{indicates text missing or illegible when filed}$$

where: C_{T} is a concentration of the material in the brine, Sw,c is an initial water saturation in the cell, Vc is a cell volume, and RQI is a reservoir quality index.

A forty-fourth aspect of this disclosure pertains to the method of aspect 43, wherein: the target resource includes lithium, the BQI is a lithium quality index (LQI), and the LQI is expressed as:

$$LQI = Σ ( RQI \times Vc \times Sw , c \times {C}_{Li} ) ,$$

where: C_{Li} is a lithium concentration in the brine.

A forty-fifth aspect of this disclosure pertains to the method of any of aspects 43 or 44, wherein: an overall reservoir quality index (RQI) is expressed by:

$$RQI = 0.0314 \sqrt{\frac{k}{ϕ}} ,$$

where: k is a permeability, and φ is a porosity.

This summary is provided to introduce a selection of concepts that are further described below in the detailed description. This summary is not intended to identify key or essential features of the claimed subject matter, nor is it intended to be used as an aid in limiting the scope of the claimed subject matter.

Additional features and advantages of embodiments of the disclosure will be set forth in the description which follows, and in part will be obvious from the description, or may be learned by the practice of such embodiments. The features and advantages of such embodiments may be realized and obtained by means of the instruments and combinations particularly pointed out in the appended claims. These and other features will become more fully apparent from the following description and appended claims or may be learned by the practice of such embodiments as set forth hereinafter.

### BRIEF DESCRIPTION OF DRAWINGS

To describe the manner in which the above-recited and other features of the disclosure can be obtained, a more particular description will be rendered by reference to specific implementations thereof which are illustrated in the appended drawings. For better understanding, the like elements have been designated by like reference numbers throughout the various accompanying figures. While some of the drawings may be schematic or exaggerated representations of concepts, at least some of the drawings may be drawn to scale. Understanding that the drawings depict some example implementations, the implementations will be described and explained with additional specificity and detail through the use of the accompanying drawings in which:

FIG. 1 is a flowchart of a method according to an example embodiment of the present disclosure.

FIG. 2 is a chart of cells in an area of interest (AOI) according to an example embodiment of the present disclosure.

FIG. 3 is a chart of cells in an AOI according to an example embodiment of the present disclosure.

FIGS. 4-12 are sets of charts of cells in an AOI according to an example embodiment of the present disclosure.

FIG. 13 is a diagram of a resource extraction operation in an AOI according to an example embodiment of the present disclosure.

FIGS. 14-15 are flowcharts of a method according to an example embodiment of the present disclosure.

FIG. 16 illustrates certain components that may be included within a computer system according to an example embodiment of the present disclosure.

Before explaining the disclosed embodiment of this disclosure in detail, it is to be understood that the invention is not limited in its application to the details of the particular arrangement shown, as the invention is capable of other embodiments. Example embodiments are illustrated in referenced figures of the drawings. It is intended that the embodiments and figures disclosed herein are to be considered illustrative rather than limiting. Also, the terminology used herein is for the purpose of description and not of limitation.

### DETAILED DESCRIPTION

While the subject disclosure applies to embodiments in many different forms, there are shown in the drawings and will be described in detail herein specific embodiments with the understanding that the present disclosure is an example of the principles of the invention. It is not intended to limit the invention to the specific illustrated embodiments. The features of the invention disclosed herein in the description, drawings, and claims can be significant, both individually and in any desired combinations, for the operation of the invention in its various embodiments. Features from one embodiment can be used in other embodiments of the invention. In the description of the drawings, like reference numerals refer to like elements.

Example embodiments of the present disclosure may provide a process to determine the most productive part of the reservoir within a land holding for the development of subsurface mineral salt resources. This process may employ elements of dynamic simulation and a notional well grid to derive the number of wells for initial(early) production. A dynamic simulation model differs from a static simulation model in that a static simulation model only considers the amount of a resource located in the area in its calculations of productivity of a well, while a dynamic simulation model considers the amount of the resource in the area that may be produced—taking into account dynamic parameters, such as a flow rate of the brine in its calculations of productivity of a well.

The method according to the disclosure, together with other quantitative tools, may be employed to define two things. First, it may demarcate the area that will undergo further subsurface reservoir characterization and dynamic simulation work related to development concept selection and the formulation of a field development plan. Second, it can determine an initial well plan for production, including, in particular, the number of wells necessary to start production. The workflow may include a deliverable representative of a one or more parameters of the reservoir, such as a quality index or recoverable lithium for a customer's area of interest (AOI). Such deliverable may be a 3D map (mapping the quality index or recoverable lithium along dimensions at surface and depth) or a two-dimensional (2D) representation (e.g., in plan view) of the parameter representative of the quality index and recoverable for the full brine reservoir depth.

This process is an improvement over the conventional art as it more definitively defines the resource “sweet spot” or optimal location in a land holding at an earlier stage in field appraisal. It also accelerates the quantitative project scoping exercise and provides better project assurance at an earlier stage in the development process than conventional methods. This assurance allows for an earlier start and conclusion to the consultative and permitting processes leading to an earlier first mineral production date.

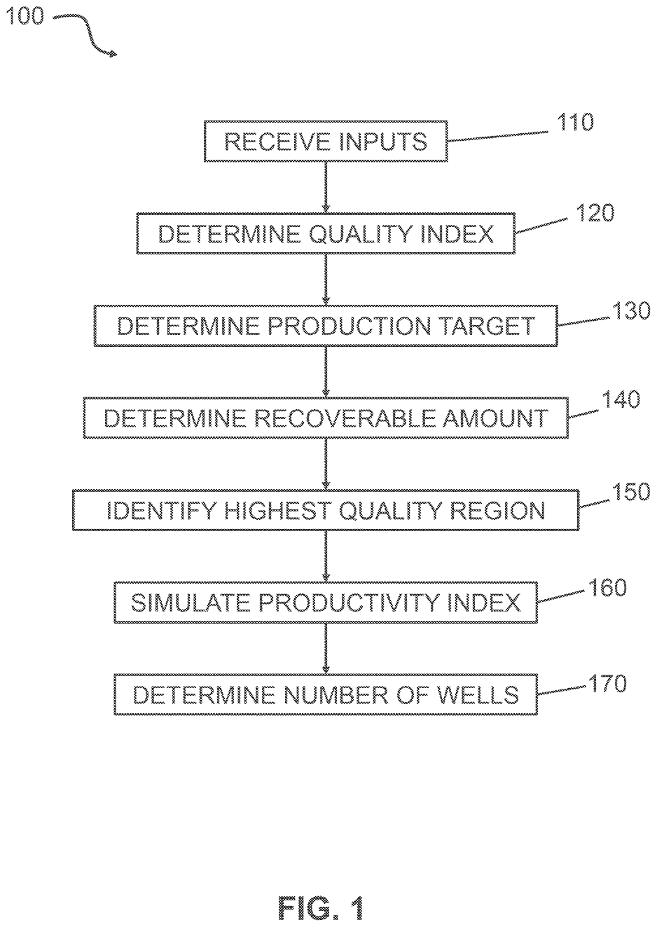

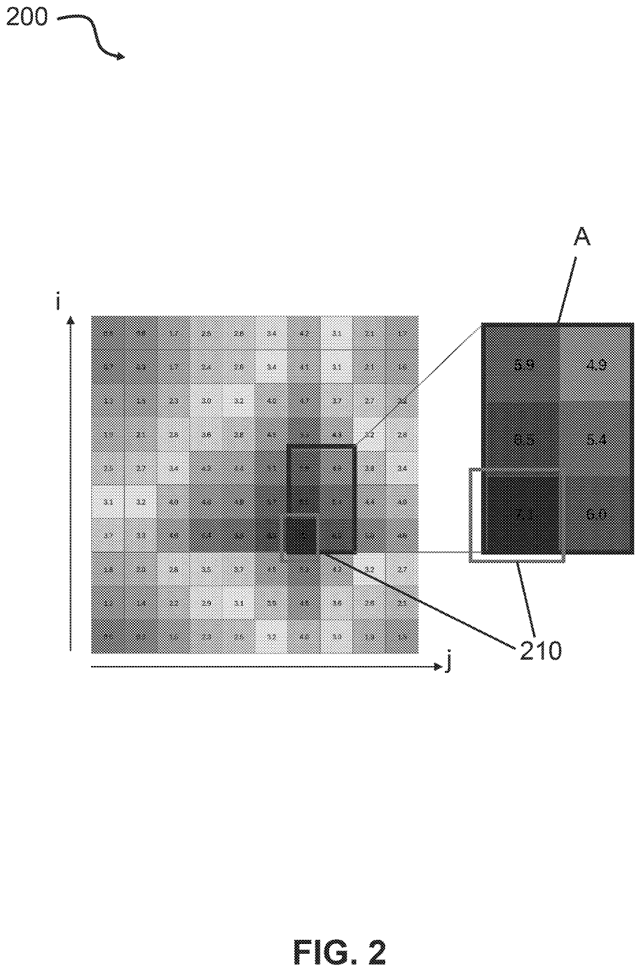

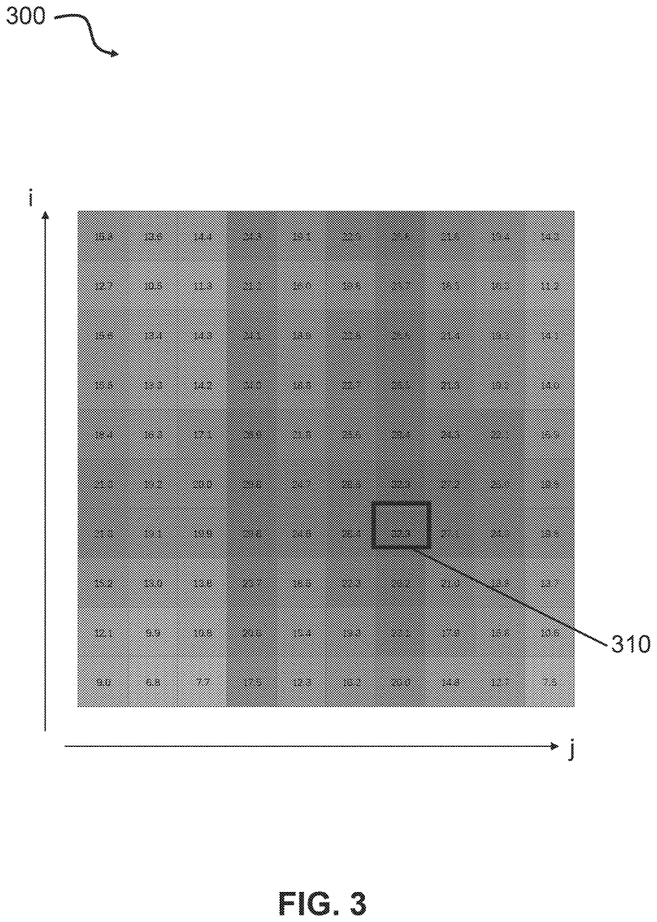

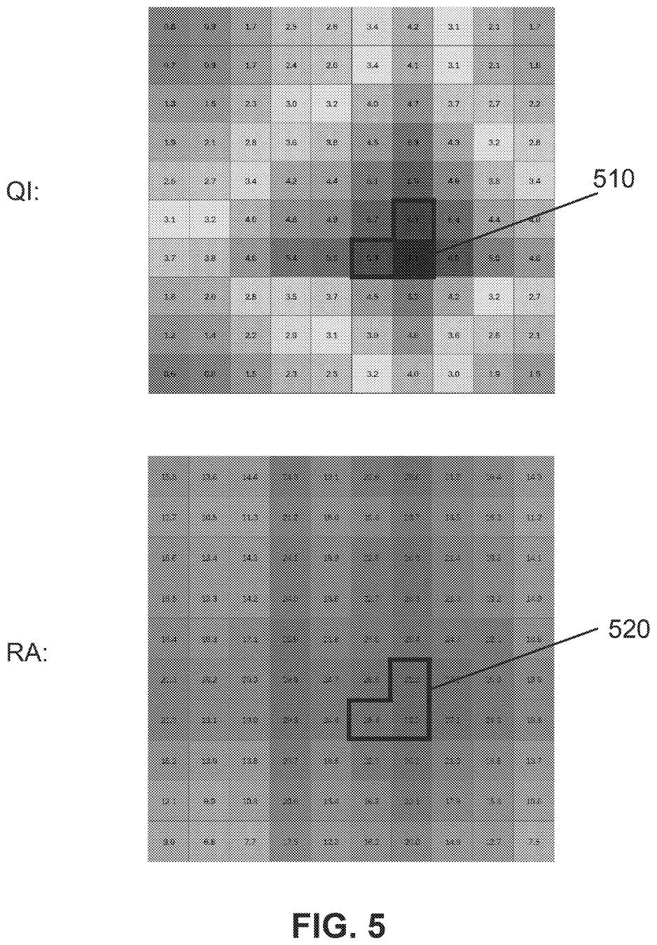

FIG. 1 is a flowchart of a method according to an example embodiment of the present disclosure. FIG. 2 is a chart of cells in an area of interest (AOI) according to an example embodiment of the present disclosure. FIG. 3 is a chart of cells in an AOI according to an example embodiment of the present disclosure. FIGS. 5-13 are sets of charts of cells in an AOI according to an example embodiment of the present disclosure.

With reference to FIG. 1, an example method 100 may include first receiving inputs (operation 110) for estimating production of a target resource in an area of interest (AOI), for example, lithium, oil, gas, and/or another mineral resource and/or brine. For example, the target resource may be lithium, but embodiments are not limited thereto. Although an example of lithium is described herein, the principles described herein may be applied to other resources, as should be understood by one of ordinary skill in the art. Examples of received inputs may include a static model, a desired period of time (e.g., a number of years) planned for resource extraction to project for the AOI, a target periodic (e.g., yearly) production rate for the target resource, and a recovery factor.

The static model provides values for the static parameters of the reservoir in the AOI, such as the permeability or the porosity of the reservoir or the concentration of the target resource. The targets for the desired period of time and periodic production rate may be inputted by an end user as a user objective for the plant. The recovery factor may be provided as an input based on data from the reservoir. In one example, the recovery factor may be manually input based on the experience of a user operator. Alternatively, an automated linear regression solution for the recovery factor for a specific reservoir, formation, or AOI may be provided.

For example, a lithium recovery factor can be produced with a conceptual reservoir simulation evaluation that varies parameters, such as well spacing, permeability, porosity, reservoir thickness, net-to-gross ratio, etc., e.g., to generate a linear regression function for the lithium recovery factor. The recovery factor may be generated, for example, via a full field simulation or via a pattern simulation that varies the input parameters. For instance, the recovery factor may be estimated based on expert knowledge and/or common knowledge about the region.

The method 100 may then determine a quality index (QI) for the target resource (operation 120) for the entire AOI. The QI may be provided, for example, as a grid or chart such that multiple locations (“cells”) across the AOI are identified and have a QI assigned to each respective location (or cell), e.g., with x-y or i-j coordinates or index identifiers. A depth value may also be assigned for each cell, for example, a z coordinate value or a k coordinate value. For example, with reference to FIG. 2, example QI values may be calculated for each cell having respective index values (i,j). In the example chart 200, the AOI may be plotted from a top-down view. In an expanded area A in FIG. 2, it can be seen that the quality index may be provided for all cells at each (i,j) location, which may be calculated over a column depth k. In the example shown in FIG. 2, the illustrated values correspond to a lithium quality index, but embodiments are not limited thereto.

In one example, lithium may be the target resource and the QI may be a lithium quality index (LQI). A lithium quality index (LQI) may be defined according to Equation 1 below:

$$LQI = Σ ( RQI \times Vc \times Sw , c \times {C}_{Li} ) \qquad [ Equation 1 ]$$

$$where :$$

$${C}_{Li} : Lithium concentration in the brine ( ppm or mg / L )$$

$$Sw , c : Initial water saturation in the cell ( fraction )$$

$$Vc : Cell volume ( reservoir barrels , RB or {m}^{3} )$$

In an example embodiment, the lithium quality index may be determined for each depth. In another example embodiment that will be described in the following, the lithium quality index for each depth may be summed over the vertical direction, e.g., so that the lithium quality index value obtained is representative of the reservoir depth and may be shown on a 2D map.

Vc is the total cell volume, not only a pore space. A calculation of φ×Vc may convert a rock volume to a pore volume (e.g., fluid volume). Sw,c may then filter out only the water-filled fraction of the pore space. LQI may therefore determine a recoverable lithium mass by accounting for how much fluid is present in a given rock volume. It should be appreciated that any units used herein are only examples, and embodiments are not limited thereto.

The LQI calculation may also be applied to any target resource (e.g., a mineral) recoverable from a brine, in which case, it may be referred to as a “Brine Quality Index (BQI)” and the variable for the concentration of lithium may be replaced with a concentration of the target resource. An LQI calculation may include additional parameters other than those shown in the example above, such as reservoir thickness.

An overall reservoir quality index (RQI) is well-known in the art, and may be determined based on the static model. In a non-limiting example, the RQI may be calculated according to Equation 2 below, but RQI may be calculated using other equations:

$$RQI = 0.0314 \sqrt{\frac{k}{ϕ}} \qquad [ Equation 2 ]$$

$$where :$$

$$k : Permeability ( mD )$$

$$ϕ : Porosity ( fraction )$$

Porosity (0) is in the denominator of Equation 2 because higher porosity increases storage, but it also lowers permeability per unit of storage. Permeability (k) may be influenced, for example, by pore-throat size, rather than simply pore volume. Thus, high porosity combined with small pore throats (e.g., “tight rock”) may result in low permeability and a lower RQI, whereas low porosity with larger pore throats (e.g., “fractured rock”) can lead to higher permeability and an increased RQI. The calculation described for a Quality Index (QI) that is provided herein is only an example of a QI calculation, and is not intended to be limiting. For example, other calculations may be included according to example embodiments.

Next, a production target value may be determined (operation 130). For example, the production target may be an amount of resource to be extracted over a period of time, e.g., daily, weekly, monthly, or yearly targets. In one example, a yearly target may be calculated according to a projected number of years of operation multiplied by the target yearly production rate. This production target value calculation may be performed before the quality index calculation and/or after some other stages of the method. In another embodiment, this operation is optional, for example, when the production target is received as an input from the end user.

Subsequently, a recoverable amount of the target resource may be determined (operation 140). The recoverable resource amount may be calculated, for example, for each previously-identified cell in the AOI, e.g., for each (i,j) index. For example, with reference to FIG. 3, a recoverable resource amount may be calculated for each cell having respective index values (i,j). In the example chart 300, the AOI may be plotted from a top-down view, and the cell locations may correspond to the cell locations identified in the FIG. 2 example. In the example shown in FIG. 3, the illustrated values correspond to an amount of recoverable lithium, but embodiments are not limited thereto. Two differences between the LQI and the recoverable resource amount for lithium is the recovery factor term and the absence of permeability dependency in the recoverable resource amount calculation.

In one example, a recoverable amount of lithium at each index location (cell) may be determined based on a recovery factor multiplied by a lithium concentration for the cell, multiplied by a fluid volume for the cell. As another example, an amount of recoverable lithium by (i,j) cells (as a summation over the depth k for the cells) may be calculated according to Equation 3 below, where RF is the recovery factor:

$$Recoverable Lithium ( kg or tons ) = \sum ( RF \times Vc \times ϕ \times Sw , c \times {C}_{Li} ) \qquad [ Equation 3 ]$$

As an example, all of the inputs for calculating the recoverable resource amount may be derived from the static model and/or manual inputs. As mentioned above, for example, the recovery factor may be manually input, e.g., based on the experience of a user operator. In another example, an automated linear regression solution may be provided for the recovery factor for a specific reservoir, formation, or AOI.

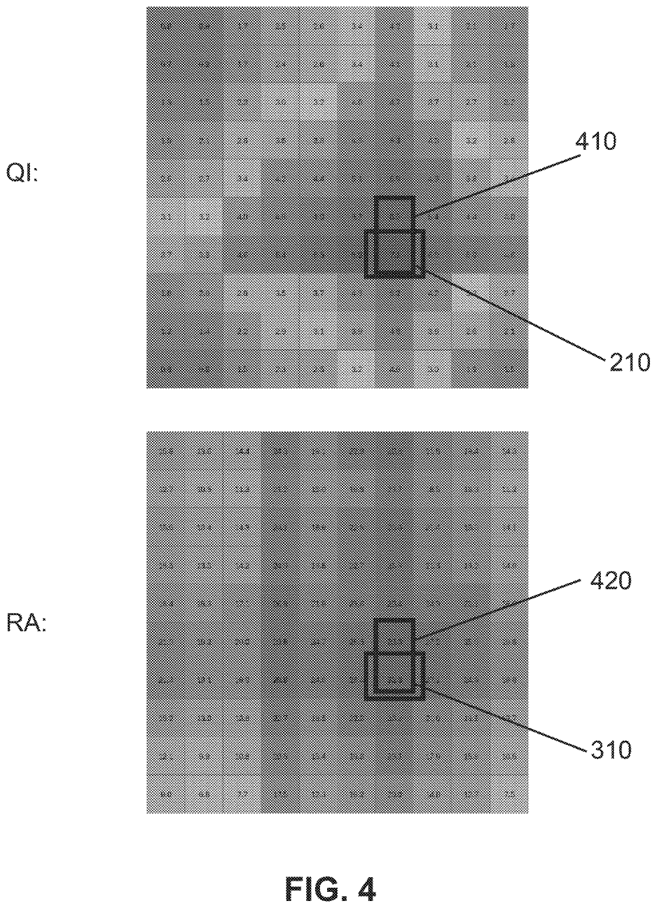

Next, a highest quality region for resource recovery may be identified (operation 150). For example, with further reference to FIGS. 2 and 4, a seed cell 210 having a highest QI (LQI in the example) value among all of the cells may be identified. In the illustrated example, the QI for seed cell 210 is 7.1, which is the highest QI value among all of the cells in the chart 200. A corresponding first recoverable amount (RA) cell 310 having the same (i,j) index as the seed cell 210 (or “first QI cell”), may be identified. In the illustrated example, the recoverable resource amount for the first RA cell 310 is 32.3. If the first RA cell 310 has a recoverable resource amount (e.g., 32.3) that is at least equal to the production target value calculated in operation 130, then the single identified cell area may be determined to be sufficient for initial production in the AOI to yield the desired amount of the resource for the desired amount of time. In the illustrated examples, values for lithium are shown in experimental results, although embodiments are not limited thereto.

If the recoverable resource amount of the first RA cell 310 is less than the production target value calculated in operation 130, then the initial production area should be expanded beyond the seed cell 210. In the illustrated examples, values for lithium are shown in experimental results, although embodiments are not limited thereto. In FIG. 4, “QI” is a chart showing QI values, similar to the chart 200 of FIG. 2, and “RA” is a chart showing a recoverable amount of the resource, similar to the chart 300 of FIG. 3. For example, as shown in FIG. 4, a first expanded QI region 410 that includes the seed cell 210 and another cell in contact with the seed cell 210 having the next-highest QI value may be identified. A first expanded RA region 420 that includes the first RA cell 310 and another cell corresponding to the other cell in contact with the seed cell 210 may then be identified, such that the first expanded RA region 420 corresponds to the same cells in the AOI as the first expanded QI region 410. All RA values for the first expanded RA region 420 may be added together, e.g., 32.3+32.3=64.6 in the illustrated example. If the first expanded RA region 420 has a total recoverable resource amount (e.g., 64.6) that is at least equal to the production target value calculated in operation 130, then the first expanded RA region 420 may be determined to be sufficient for initial production in the AOI to yield the desired amount of the resource for the desired amount of time.

If the calculated recoverable resource amount for the first expanded RA region 420 is less than the production target value calculated in operation 130, then the initial production area should be expanded beyond the first expanded QI region 410. In FIG. 5, “QI” is a chart showing QI values, similar to the chart 200 of FIG. 2, and “RA” is a chart showing a recoverable amount of the resource, similar to the FIG. 3 example. For example, as shown in FIG. 5, a second expanded QI region 510 that includes the first expanded QI region 410 and another cell in contact with the first expanded QI region 410 having the next-highest QI value may be identified. A second expanded RA region 520 that includes the first expanded RA region 420 and another cell corresponding to the other cell in contact with the first expanded QI region 410 may then be identified, such that the second expanded RA region 520 corresponds to the same cells in the AOI as the second expanded QI region 510. All RA values for the second expanded RA region 520 may be added together, e.g., 32.3+32.3+28.4=93.0 in the illustrated example. If the second expanded RA region 520 has a total recoverable resource amount (e.g., 93.0) that is at least equal to the production target value calculated in operation 130, then the second expanded RA region 520 may be determined to be sufficient for initial production in the AOI to yield the desired amount of the resource for the desired amount of time.

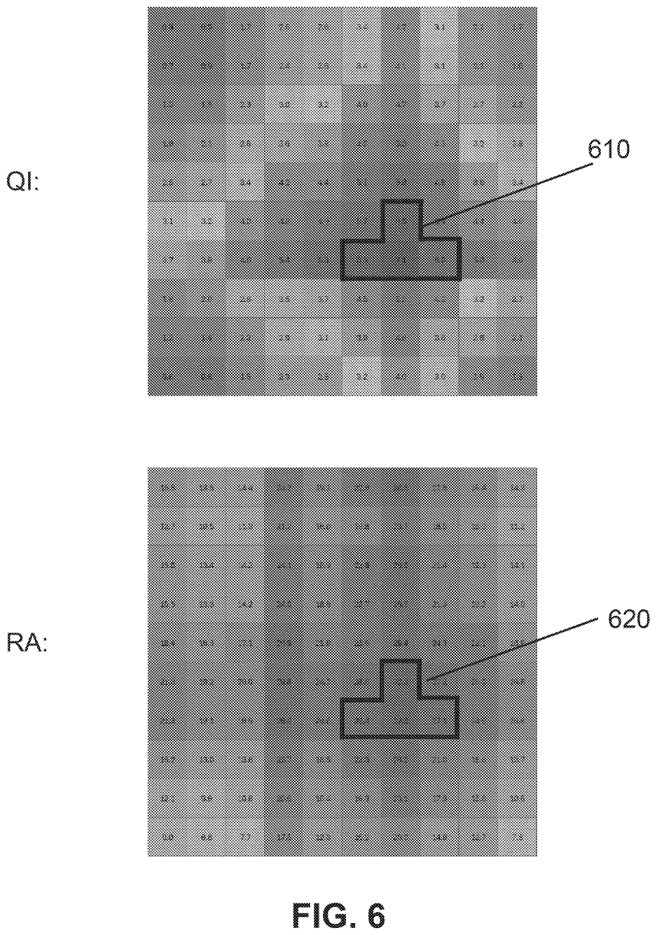

If the calculated recoverable resource amount for the second expanded RA region 520 is less than the production target value calculated in operation 130, then the initial production area should be expanded beyond the second expanded QI region 510. In FIG. 6, “QI” is a chart showing QI values, similar to the chart 200 of FIG. 2, and “RA” is a chart showing a recoverable amount of the resource, similar to the FIG. 3 example. For example, as shown in FIG. 6, a third expanded QI region 610 that includes the second expanded QI region 510 and another cell in contact with the second expanded QI region 510 having the next-highest QI value may be identified. A third expanded RA region 620 that includes the second expanded RA region 520 and another cell corresponding to the other cell in contact with the second expanded QI region 510 may then be identified, such that the third expanded RA region 620 corresponds to the same cells in the AOI as the third expanded QI region 610. All RA values for the third expanded RA region 620 may be added together, e.g., 32.3+32.3+28.4+27.1=120.1 in the illustrated example. If the third expanded RA region 620 has a total recoverable resource amount (e.g., 120.1) that is at least equal to the production target value calculated in operation 130, then the third expanded RA region 620 may be determined to be sufficient for initial production in the AOI to yield the desired amount of the resource for the desired amount of time.

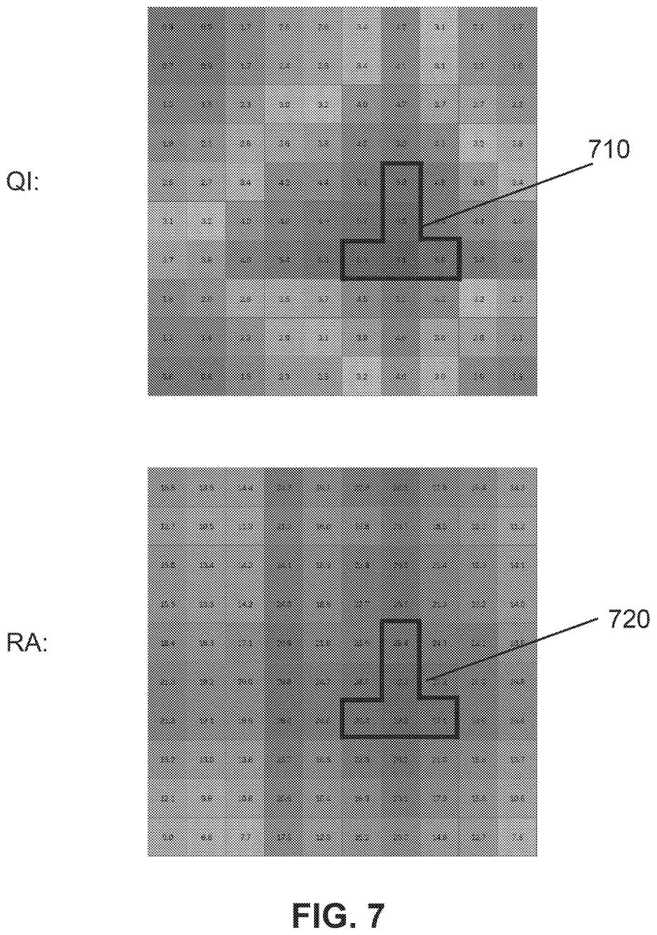

If the calculated recoverable resource amount for the third expanded RA region 620 is less than the production target value calculated in operation 130, then the initial production area should be expanded beyond the third expanded QI region 610. In FIG. 7, “QI” is a chart showing QI values, similar to the chart 200 of FIG. 2, and “RA” is a chart showing a recoverable amount of the resource, similar to the FIG. 3 example. For example, as shown in FIG. 7, a fourth expanded QI region 710 that includes the third expanded QI region 610 and another cell in contact with the third expanded QI region 610 having the next-highest QI value may be identified. A fourth expanded RA region 720 that includes the third expanded RA region 620 and another cell corresponding to the other cell in contact with the third expanded QI region 610 may then be identified, such that the fourth expanded RA region 720 corresponds to the same cells in the AOI as the fourth expanded QI region 710. All RA values for the fourth expanded RA region 720 may be added together, e.g., 32.3+32.3+28.4+27.1+29.4=149.5 in the illustrated example. If the fourth expanded RA region 720 has a total recoverable resource amount (e.g., 149.5) that is at least equal to the production target value calculated in operation 130, then the fourth expanded RA region 720 may be determined to be sufficient for initial production in the AOI to yield the desired amount of the resource for the desired amount of time.

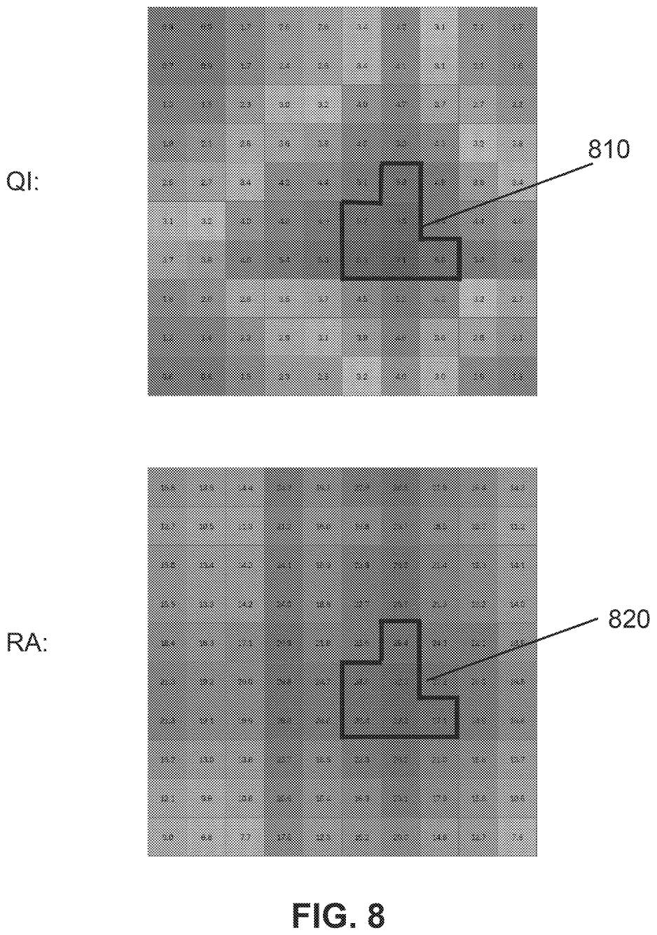

If the calculated recoverable resource amount for the fourth expanded RA region 720 is less than the production target value calculated in operation 130, then the initial production area should be expanded beyond the fourth expanded QI region 710. In FIG. 8, “QI” is a chart showing QI values, similar to the chart 200 of FIG. 2, and “RA” is a chart showing a recoverable amount of the resource, similar to the FIG. 3 example. For example, as shown in FIG. 8, a fifth expanded QI region 810 that includes the fourth expanded QI region 710 and another cell in contact with the fourth expanded QI region 710 having the next-highest QI value may be identified. A fifth expanded RA region 820 that includes the fourth expanded RA region 720 and another cell corresponding to the other cell in contact with the fourth expanded QI region 710 may then be identified, such that the fifth expanded RA region 820 corresponds to the same cells in the AOI as the fifth expanded QI region 810. All RA values for the fifth expanded RA region 820 may be added together, e.g., 32.3+32.3+28.4+27.1+29.4+28.5=178.0 in the illustrated example. If the fifth expanded RA region 820 has a total recoverable resource amount (e.g., 178.0) that is at least equal to the production target value calculated in operation 130, then the fifth expanded RA region 820 may be determined to be sufficient for initial production in the AOI to yield the desired amount of the resource for the desired amount of time.

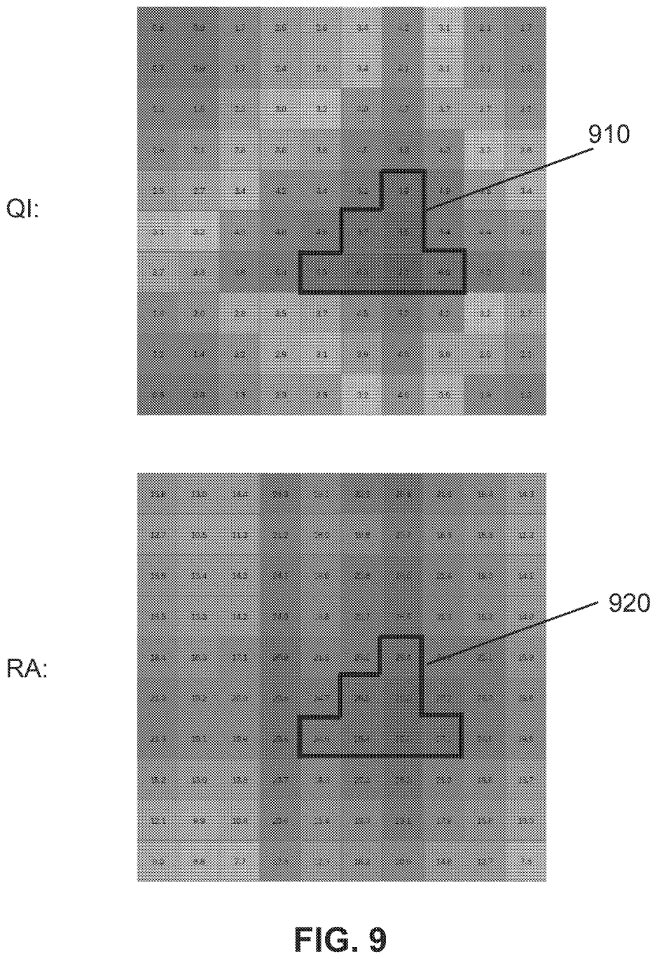

If the calculated recoverable resource amount for the fifth expanded RA region 820 is less than the production target value calculated in operation 130, then the initial production area should be expanded beyond the fifth expanded QI region 810. In FIG. 9, “QI” is a chart showing QI values, similar to the chart 200 of FIG. 2, and “RA” is a chart showing a recoverable amount of the resource, similar to the FIG. 3 example. For example, as shown in FIG. 9, a sixth expanded QI region 910 that includes the fifth expanded QI region 810 and another cell in contact with the fifth expanded QI region 810 having the next-highest QI value may be identified. A sixth expanded RA region 920 that includes the fifth expanded RA region 820 and another cell corresponding to the other cell in contact with the fifth expanded QI region 810 may then be identified, such that the sixth expanded RA region 920 corresponds to the same cells in the AOI as the sixth expanded QI region 910. All RA values for the sixth expanded RA region 920 may be added together, e.g., 32.3+32.3+28.4+27.1+29.4+28.5+24.6=202.6 in the illustrated example. If the sixth expanded RA region 920 has a total recoverable resource amount (e.g., 202.6) that is at least equal to the production target value calculated in operation 130, then the sixth expanded RA region 920 may be determined to be sufficient for initial production in the AOI to yield the desired amount of the resource for the desired amount of time.

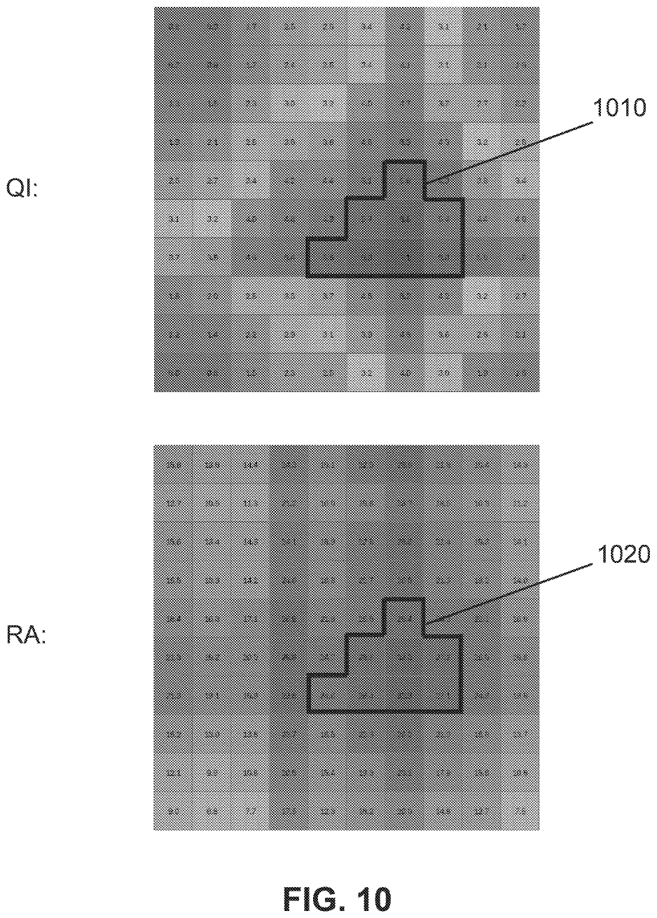

If the calculated recoverable resource amount for the sixth expanded RA region 920 is less than the production target value calculated in operation 130, then the initial production area should be expanded beyond the sixth expanded QI region 910. In FIG. 10, “QI” is a chart showing QI values, similar to the chart 200 of FIG. 2, and “RA” is a chart showing a recoverable amount of the resource, similar to the FIG. 3 example. For example, as shown in FIG. 10, a seventh expanded QI region 1010 that includes the sixth expanded QI region 910 and another cell in contact with the sixth expanded QI region 910 having the next-highest QI value may be identified. A seventh expanded RA region 1020 that includes the sixth expanded RA region 920 and another cell corresponding to the other cell in contact with the sixth expanded QI region 910 may then be identified, such that the seventh expanded RA region 1020 corresponds to the same cells in the AOI as the seventh expanded QI region 1010. All RA values for the seventh expanded RA region 1020 may be added together, e.g., 32.3+32.3+28.4+27.1+29.4+28.5+24.6+27.2=229.8 in the illustrated example. If the seventh expanded RA region 1020 has a total recoverable resource amount (e.g., 229.8) that is at least equal to the production target value calculated in operation 130, then the seventh expanded RA region 1020 may be determined to be sufficient for initial production in the AOI to yield the desired amount of the resource for the desired amount of time.

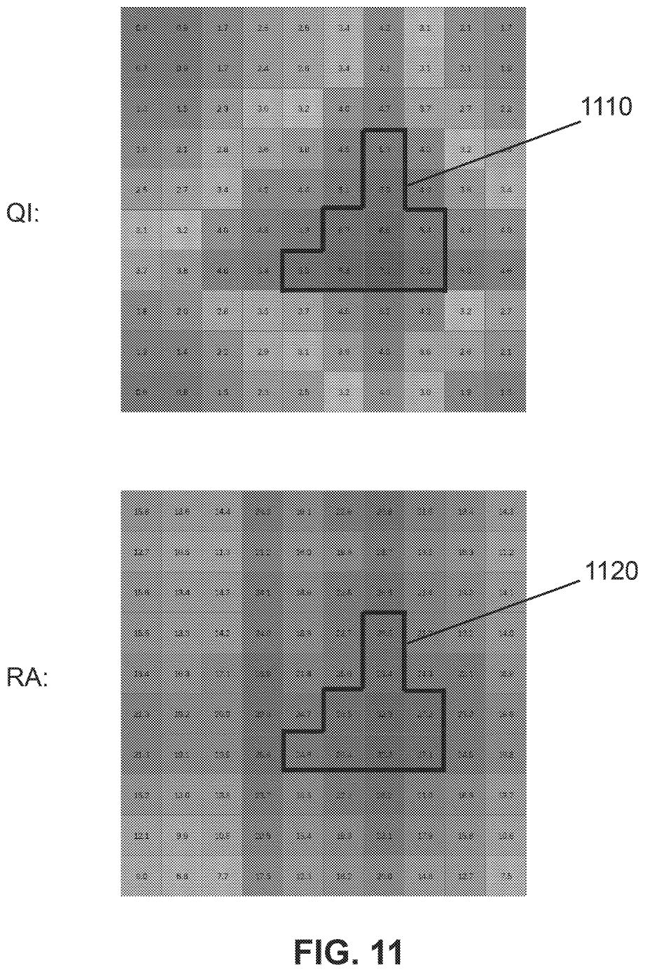

If the calculated recoverable resource amount for the seventh expanded RA region 1020 is less than the production target value calculated in operation 130, then the initial production area should be expanded beyond the seventh expanded QI region 1010. In FIG. 11, “QI” is a chart showing QI values, similar to the chart 200 of FIG. 2, and “RA” is a chart showing a recoverable amount of the resource, similar to the FIG. 3 example. For example, as shown in FIG. 11, an eighth expanded QI region 1110 that includes the seventh expanded QI region 1010 and another cell in contact with the seventh expanded QI region 1010 having the next-highest QI value may be identified. An eighth expanded RA region 1120 that includes the seventh expanded RA region 1020 and another cell corresponding to the other cell in contact with the seventh expanded QI region 1010 may then be identified, such that the eighth expanded RA region 1120 corresponds to the same cells in the AOI as the eighth expanded QI region 1110. All RA values for the eighth expanded RA region 1120 may be added together, e.g., 32.3+32.3+28.4+27.1+29.4+28.5+24.6+27.2+26.5=256.3 in the illustrated example. If the eighth expanded RA region 1120 has a total recoverable resource amount (e.g., 256.3) that is at least equal to the production target value calculated in operation 130, then the eighth expanded RA region 1120 may be determined to be sufficient for initial production in the AOI to yield the desired amount of the resource for the desired amount of time.

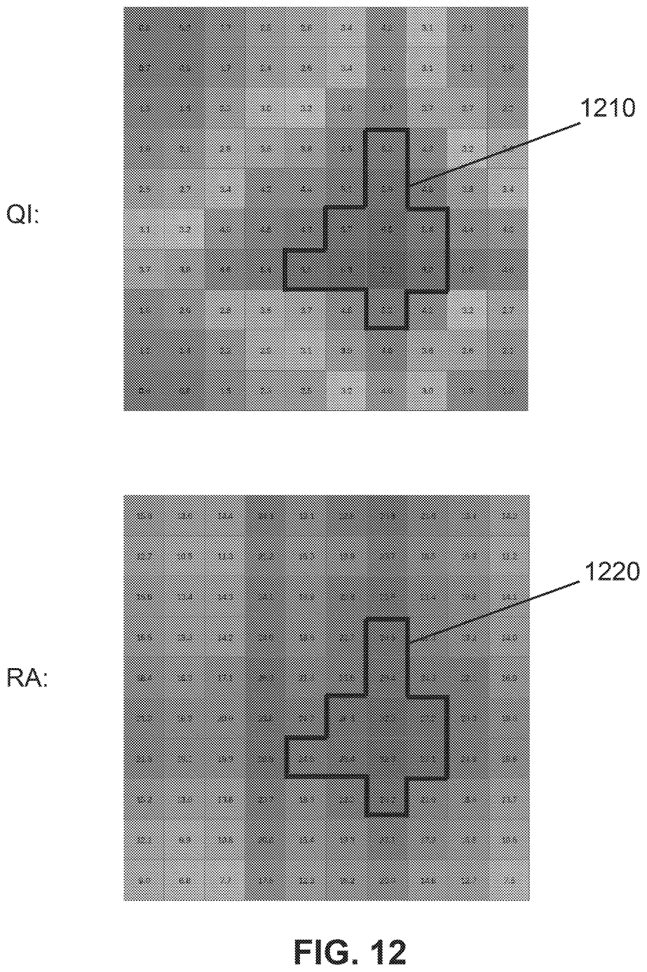

If the calculated recoverable resource amount for the eighth expanded RA region 1120 is less than the production target value calculated in operation 130, then the initial production area should be expanded beyond the eighth expanded QI region 1110. In FIG. 12, “QI” is a chart showing QI values, similar to the chart 200 of FIG. 2, and “RA” is a chart showing a recoverable amount of the resource, similar to the FIG. 3 example. For example, as shown in FIG. 12, a ninth expanded QI region 1210 that includes the eighth expanded QI region 1110 and another cell in contact with the eighth expanded QI region 1110 having the next-highest QI value may be identified. A ninth expanded RA region 1220 that includes the eighth expanded RA region 1120 and another cell corresponding to the other cell in contact with the eighth expanded QI region 1110 may then be identified, such that the ninth expanded RA region 1220 corresponds to the same cells in the AOI as the ninth expanded QI region 1210. All RA values for the ninth expanded RA region 1220 may be added together, e.g., 32.3+32.3+28.4+27.1+29.4+28.5+24.6+27.2+26.5+26.2=282.5 in the illustrated example. If the ninth expanded RA region 1220 has a total recoverable resource amount (e.g., 282.5) that is at least equal to the production target value calculated in operation 130, then the ninth expanded RA region 1220 may be determined to be sufficient for initial production in the AOI to yield the desired amount of the resource for the desired amount of time.

It is possible that multiple areas of equally high resource recovery availability may be identified. In one example, only one area may be expanded, and in another example, half of two distinct areas may be expanded. This may occur, for example, where there is more than one “concentration bullseye” in an AOI, e.g., where there are multiple areas having a relatively high QI centered on a cell with gradually decreasing QI cells surrounding the high-QI cell.

After a region of cells that could yield the desired amount of the resource for the desired amount of time has been identified in operation 150 as a highest quality region (or “region of interest” or “ROI”), a productivity index may be determined by simulation in the identified highest quality region (operation 160). The productivity index (PI) may be defined for a representative number of well locations across the region for a representative time period. For example, a 30-day simulation may be run for each well in turn to estimate an expected output to determine a respective PI for each well at an estimated pressure drop value. An average of the PI values may be calculated, and the calculated (determined) average value may be assigned to the region as a regional PI value.

The productivity index for each well may be determined as follows. A local dynamic simulation may be run in each well, for example, considering that other wells are closed, e.g., no fluid is flowing through the other wells. The local dynamic simulation may be performed by applying a linear flow rate equation. The brine flow rate (Qbrine) in the well depends on porosity and permeability. The dynamic simulation may also use, on top of the static model as an input, parameters set by the user, such as the drawdown pressure. Brine extraction flow rate, or target resource extraction flow rate (e.g., calculated based on brine extraction flow rate and concentration of the target resource in the brine) may all be recorded at the end of each dynamic simulation time operation, and average rates may then be calculated over the duration of each dynamic simulation run for each well. Once all dynamic simulation runs are completed, the averaged inflow rates for brine, and target resource, and/or heat may each be divided by the constant bottom hole pressure drawdown as set in the dynamic simulation runs to derive a productivity index for brine inflow and/or target resource inflow.

As part of the operation described above, it may also be determined whether there are any rate sensitivities upon the productivity indices. This may include running the dynamic simulation while equally increasing bottom hole pressure drawdown in the representative well. The productivity indices may then be calculated from the averaged production rates over the simulation time interval and compared to determine whether they are approximately constant over these increasing pressure drawdown increments. If these productivity indices are found to materially change with increasing bottom hole pressure drawdown, there is a rate sensitivity present in the hydraulic connectivity of the dynamic simulator. If a rate sensitivity is present, a transform may be generated using the results from this well subset to adjust these productivity indices for bottom hole pressure drawdown. If there is no rate sensitivity present, then the bottom hole pressure drawdown increment used in subsequent dynamic simulation runs may be considered to be immaterial to the productivity index calculations.

If a comparison is to be made between the inflow performance of a vertical well and that for a horizontal well with varying lateral section lengths, each lateral section length for each notional well may be first converted into a negative skin factor, set as such in the dynamic simulation, and the entire exercise may be performed an additional time for every lateral section length. Should the reservoir contain natural fractures, each representative horizontal well may be built into the dynamic simulation, each lateral section allowed to intersect these fractures, and the exercise performed additional times to account for both horizontal section length and orientation relative to the natural fractures.

The productivity index determination in the method of FIG. 1 is performed only for the highest quality region. However, in other embodiments, it could be performed for the entire region that is under scrutiny using the static model inputs, without having performed operations 120-150.

Next, an initial number of wells may be determined to meet the production target value, e.g., a yearly production rate, that will be achieved starting when the wells are first activated in the region of interest (ROI) in the overall AOI (operation 170). For example, an average target resource concentration for all cells in the ROI may be calculated. Then, the number of wells initially required to produce the target amount of the target resource may be calculated, for example, by multiplying the average target resource concentration by the desired periodic (e.g., daily, weekly, monthly, or yearly) production rate, and dividing the product by the average PI value for the ROI calculated in operation 160.

In one example, an initial number of wells to extract lithium may be determined by multiplying the average lithium concentration by the desired yearly lithium production rate, and dividing the product by the average PI value for the ROI calculated in operation 160.

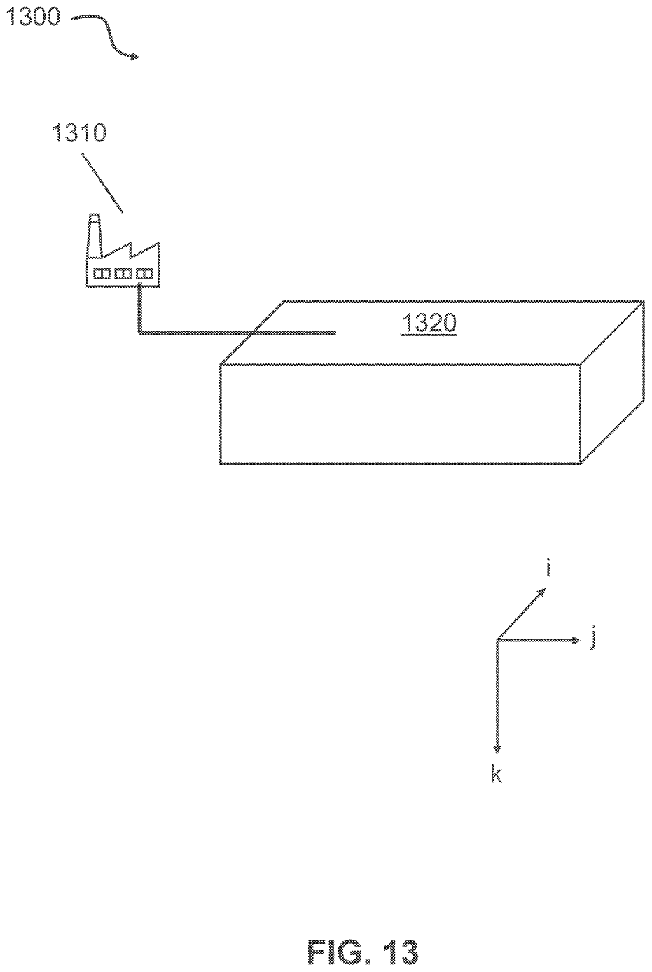

FIG. 13 is a diagram of a resource extraction operation in an AOI according to an example embodiment of the present disclosure.

The determined number of wells and ROI identification may be used to set up and operate a resource extraction operation, e.g., resource extraction operation 1300 in FIG. 13, in the AOI, e.g., AOI 1320. Example embodiments may provide a workflow that is more flexible than a static model, but is less calculation-intense than a full dynamic simulation. The resource extraction operation may have a project timeline that can grow with a provided infrastructure. For example, the operation may be scaled with available production and/or refining capabilities. As an example, a surface facility 1310 may be built for extracting and/or refining the target resource, e.g., lithium, gas, oil, a mineral, or a brine, as the resource is extracted from the ground, rather than pumping brine into a lake and waiting for evaporation. The facility may be capable of processing a certain volume of fluid (or brine) per day, which may be determined to be an operative flow rate. The production target value may be set to be close to the operative flow rate, for example, to increase or maximize efficiency of the resource extraction operation. The ROI may be expanded through the AOI over time, for example, to maintain a steady rate of resource (e.g., brine) flow to the facility, e.g., to maximize facility usage.

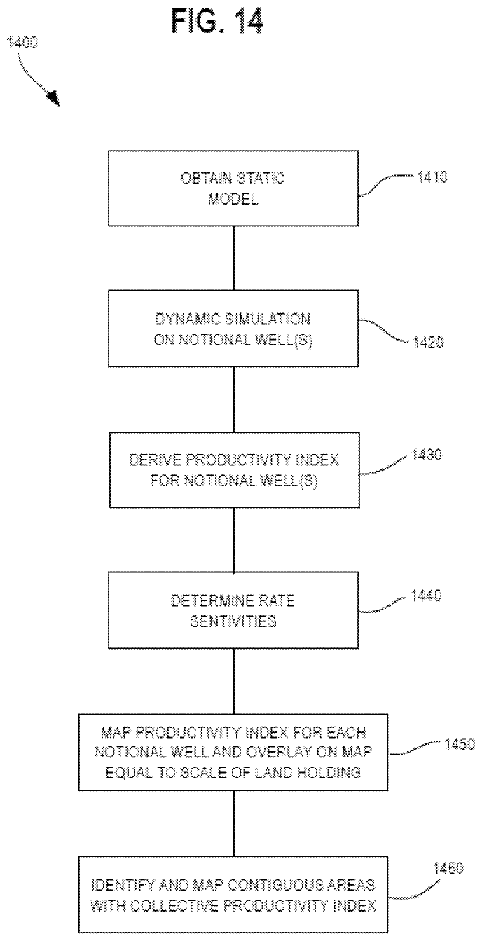

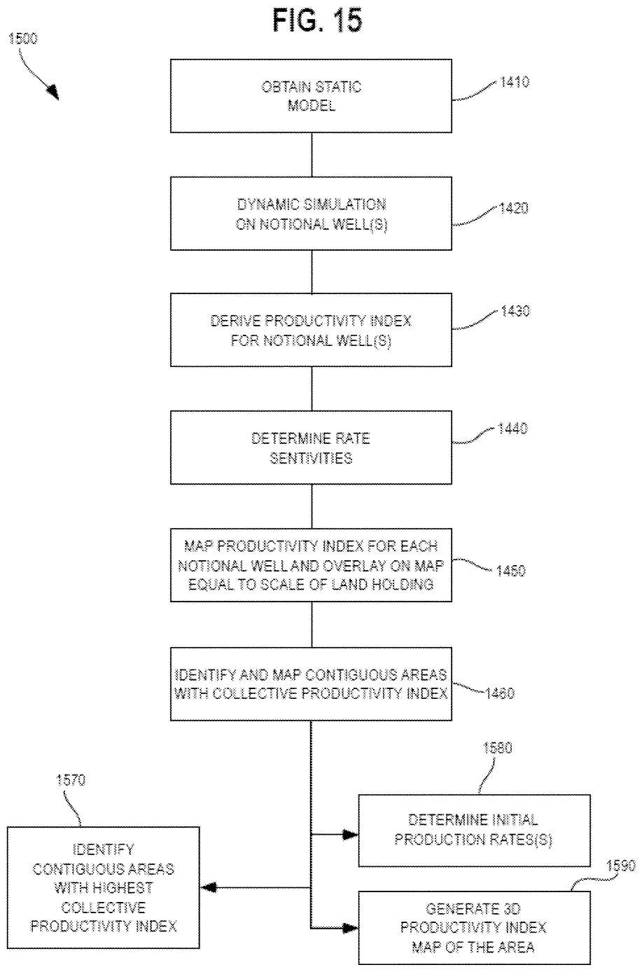

FIGS. 14-15 are flowcharts of a method according to an example embodiment of the present disclosure.

With reference to FIGS. 14-15, a method 1400 according to an example embodiment may include an operation 1410 of obtaining a static model of the formation that provides parameters of the formation including porosity thickness, permeability, salt concentration as well as other optional parameters. Such parameters may be measured in some locations, inferred in some other locations based on the subsurface lithology or calculated based on other measured parameters.

At operation 1420, a productivity index is obtained for a plurality of “notional wells” using a local dynamic simulation as explained in relationship with the method of FIG. 14. A small subset of “notional” wells may be taken that may be evenly placed throughout the notional well grid. Several dynamic simulation runs may be performed for each of these “opened” notional wells, other “notional” wells of the grid being closed. The dynamic simulation on the “opened” notional well may then be performed to determine its brine extraction rate, mineral salt extraction rate, and/or heat inflow rate (operation 1420). Such rates are obtained using a linear flow rate equation.

The dynamic simulation also uses the static model as an input, such as the porosity and permeability, as well as parameters set by the user, such as the drawdown pressure. This selection of a single notional well in the grid may be continued until every notional well has had a dynamic simulation performed as in the manner described. Brine extraction, mineral salt extraction, and heat inflow rates may all be recorded at the end of each dynamic simulation time operation, and average rates may then be calculated over the duration of each dynamic simulation run. Every dynamic simulation, for each notional well, should be run for an equivalent period of elapsed time.

Once all dynamic simulation runs may be completed for every notional well, the averaged inflow rates for brine, mineral salt, and/or heat may each be divided by the constant bottom hole pressure drawdown as set in the dynamic simulation runs to derive a productivity index for brine inflow, mineral salt inflow, and heat inflow (operation 1430).

It may also be determined if there are any rate sensitivities upon the productivity indices for brine, mineral salt, and/or heat (operation 1440). It includes running the dynamic simulation while equally increasing bottom hole pressure drawdown in the “notional” well. The productivity indices may then be calculated from the averaged production rates over the simulation time interval and compared to determine if they are approximately constant over these increasing pressure drawdown increments. If these productivity indices are found to materially change with increasing bottom hole pressure drawdown, there is a rate sensitivity present in the hydraulic connectivity of the dynamic simulator. If a rate sensitivity is present, a transform may be generated using the results from this well subset to adjust these productivity indices for bottom hole pressure drawdown. If there is no rate sensitivity present, then the bottom hole pressure drawdown increment used in subsequent dynamic simulation runs is immaterial to the productivity index calculations.

If a comparison is to be made between the inflow performance of a vertical well and that for a horizontal well with varying lateral section lengths, each lateral section length for each notional well may be first converted into a negative skin factor, set as such in the dynamic simulation, and the entire exercise may be performed an additional time for every lateral section length. Should the reservoir contain natural fractures, each notional horizontal well may be built into the dynamic simulation, each lateral section allowed to intersect these fractures, and the exercise performed additional times to account for both horizontal section length and orientation relative to the natural fractures.

The calculated productivity indices for each notional well may next be plotted in two dimensions and may be overlain upon a map of equal scale to the boundaries of the land holding (operation 1450). Separate maps may be made to display the spatial distributions of brine productivity index, mineral salt productivity index, and heat productivity index. A color scale may be employed on these maps to differentiate the notional wells with higher relative inflow potential from those with lower relative inflow potential. From these preliminary results, the color distribution may visually display the most potentially productive mineral salt and heat areas within the land holding.

Using the productivity index values, a collective productivity index may be summed within contiguous areas of progressively increasing size within all possible locations for the given shape at every point that it fits into the land holding boundaries (operation 1460). These contiguous areas can be squares or rectangles of any aspect ratio. The shape may be first placed, for example, into the bottom left-hand corner of the land holding, a collective productivity index may be summed over all the notional wells, then the shape may be moved up one notional well at a time, until the upper boundary of the land holding is reached. Then, the shape may be moved directly down back to the bottom of the land holding boundary and moved one notional well to the right. The shape may then be moved upwards again, one notional well at a time, taking sums of the collective productivity index until the upper land holding boundary is again reached. The process may be repeated until the shape reaches the upper right corner of the land holding boundary and no more collective productivity indices can be summed. The contiguous areas of successively increasing size for the highest and lowest collective inflow indices are outlined onto the land holding map and these overlapping boundaries graphically display the area within the land holding with the most and least potentially productive mineral salt and heat resources. It should be appreciated that the locations and directions described above are included as an example to aid in comprehension, and the disclosure is not limited thereto.

In certain embodiments, in an example method 1500 that continues from the example method 1400, the most potentially productive area may be defined at this point represents that part of the land holding where additional subsurface characterization and dynamic simulation work should proceed to formulate the preferred development concept (operation 1570). This operation is optional. The least potentially productive area at this point represents the area that defines where subsurface work can likely be deferred. All areas lying between the most and least potentially productive areas within the land holding represent areas where subsurface work may proceed regarding subsequent phased development(s) over time to address declining mineral salt and/or heat input rates with step-out drilling to maintain product production rates at a constant level over a specified interval of time.

Although it may not be possible to change the nature of the reservoir properties, it is possible to change the number of wells and/or the well spacing. A regression equation derived from a static model may solve for the well spacing and the required number of wells to determine resource (e.g., lithium) volume. Thus, acreage size may be derived after the location is identified.

In certain embodiments, in the example method 1500, with a best acreage defined within the land holding, it can now be utilized to determine the initial production rates for brine, mineral salt, and heat without having first to formulate a preferred development concept (operation 1580).

This operation is optional. This operation may begin with one of two alternative processes. The first process sets the plant product manufacturing rate and then determines the number of production and injection wells required to achieve this stated product rate. The second process initially sets the total project budget amount and then selects an increasing number of production and injection wells to determine the plant product manufacturing rate, varying both well count and plant rate, allocating budget money between the wells and the plant until the budget is consumed. Thus, the initial scope of the development can be assured at an earlier place in the project approvals stage gate than under the prior art. In certain embodiments, a deliverable representative of a three-dimensional productivity index of the area of interest (AOI) may be generated (operation 1590).

To refine the development project scope, at this point a determination may be made as to whether mineral salt or heat is the primary product produced. First, some initial work may be performed to set the generalized artificial lift type and well piping configuration that can accommodate the expected range(s) of liquid flow rate(s) and temperature(s). If a rate sensitivity was found present in the dynamic simulator, the transform generated earlier may be employed to correct the inflow rates to the bottom hole pressure drawdown increments.

If a mineral salt (e.g., a commercial material) is the primary product to be extracted, a nodal analysis routine may be employed to first back-calculate the resulting maximum operating drawdown pressure in each notional producing well. This maximum bottom hole drawdown pressure may set the maximum brine and therefore mineral salt production rate for each notional well. This down hole pressure drop may be iteratively determined between the plant operating inlet and each notional well's perforation mid-point, and may account for all intervening equipment and energy losses. Then a heat loss calculation may be performed for the resulting brine flow rate if there is an expectation to recover heat from the brine.

If heat is the primary product to be extracted, the nodal analysis routine may also employ a heat loss calculation performed concurrently with the down hole pressure drop calculation. With either mineral salt or heat as the primary product, the mineral salt production rate is dependent upon the brine production rate, which may or may not be constrained by an additional heat constraint on the primary product facility.

Once this operating pressure draw down is determined for each notional well within and immediately surrounding the derived best acreage, it may be multiplied by the productivity index to determine the brine, mineral salt, and heat production rates for each of these notional wells as such:
If the plant product manufacturing rate is set, then the salt and/or heat rate for successive wells may be summed until enough salt and/or heat is initially produced (which may include some redundancy) to meet this plant rate.
If the budget amount is set first, then the iterative budget allocation exercise described earlier may be performed until the budget is consumed, expenditures may be allocated between wells and plant, and the plant product manufacturing rate may then be determined by the number of wells the total budget will allow.

At this point, the process may be completed and either the development project capital budget or the plant product manufacturing rate may be set.

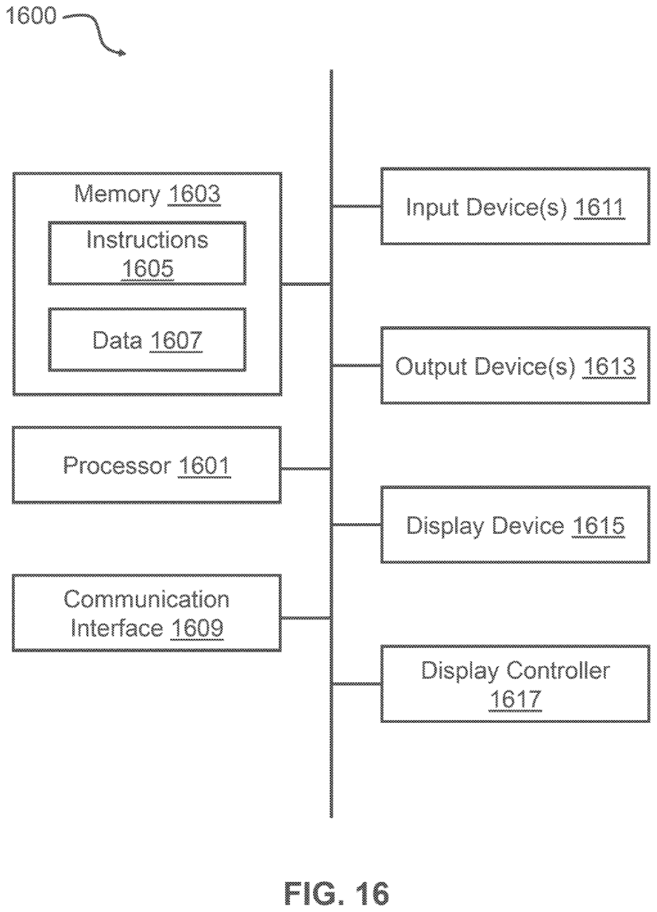

FIG. 16 illustrates certain components that may be included within a computer system according to an example embodiment of the present disclosure.

FIG. 16 illustrates certain components that may be included within a computer system 1600, which may be used to control features according to embodiments of the present disclosure, such as the features discussed above with reference to FIGS. 1-15. One or more computer systems 1600 may be used to implement the various devices, components, and systems described herein.

The computer system 1600 includes a processor 1601. The processor 1601 may be a single processor or may include multiple processors and/or sub-processors. The processor 1601 may be a general-purpose single- or multi-chip microprocessor (e.g., an Advanced RISC (Reduced Instruction Set Computer) Machine (ARM)), a special-purpose microprocessor (e.g., a digital signal processor (DSP)), a microcontroller, a programmable gate array, etc. The processor 1601 may be referred to as a central processing unit (CPU). Although just a single processor 1601 is shown in the computer system 1600 of FIG. 16, in an alternative configuration, a combination of processors (e.g., an ARM and DSP) could be used. In one or more embodiments, the computer system 1600 further includes one or more graphics processing units (GPUs), which can provide processing services related to both entity classification and graph generation.

The computer system 1600 also includes memory 1603 in electronic communication with the processor 1601. The memory 1603 may be any electronic component capable of storing electronic information. For example, the memory 1603 may be embodied as random access memory (RAM), read-only memory (ROM), magnetic disk storage media, optical storage media, flash memory devices in RAM, on-board memory included with the processor, erasable programmable read-only memory (EPROM), electrically erasable programmable read-only memory (EEPROM) memory, registers, and so forth, including combinations thereof.

Instructions 1605 and data 1607 may be stored in the memory 1603. The instructions 1605 may be executable by the processor 1601 to implement some or all of the functionality disclosed herein. Executing the instructions 1605 may involve the use of the data 1607 that is stored in the memory 1603. Any of the various examples of modules and components described herein may be implemented, partially or wholly, as instructions 1605 stored in memory 1603 and executed by the processor 1601. Any of the various examples of data described herein may be among the data 1607 that is stored in memory 1603 and used during execution of the instructions 1605 by the processor 1601.

A computer system 1600 may also include one or more communication interfaces 1609 for communicating with other electronic devices. The communication interface(s) 1609 may be based on wired communication technology, wireless communication technology, or both. Some examples of communication interfaces 1609 include a Universal Serial Bus (USB), an Ethernet adapter, a wireless adapter that operates in accordance with an Institute of Electrical and Electronics Engineers (IEEE) 802.11 wireless communication protocol, a Bluetooth® wireless communication adapter, and an infrared (IR) communication port.

A computer system 1600 may also include one or more input devices 1611 and one or more output devices 1613. Some examples of input devices 1611 include a keyboard, mouse, microphone, remote control device, button, joystick, trackball, touchpad, and lightpen. Some examples of output devices 1613 include a speaker and a printer. One specific type of output device that is typically included in a computer system 1600 is a display device 1615. Display devices 1615 used with embodiments disclosed herein may utilize any suitable image projection technology, such as liquid crystal display (LCD), light-emitting diode (LED), gas plasma, electroluminescence, or the like. A display controller 1617 may also be provided, for converting data 1607 stored in the memory 1603 into text, graphics, and/or moving images (as appropriate) shown on the display device 1615.

The various components of the computer system 1600 may be coupled together by one or more buses, which may include a power bus, a control signal bus, a status signal bus, a data bus, etc. For the sake of clarity, the various buses are illustrated in FIG. 16 as a bus system 1619.

Following are sections in accordance with at least one embodiment of the present disclosure:

Clause 1: A method, including: receiving inputs for estimating production of a target resource from a resource extraction operation in an area of interest (AOI), the inputs including a recovery factor for the target resource in the AOI, one or more objectives for the resource extraction, and one or more parameters of the AOI, the one or more parameters of the AOI including one or more of: a porosity of the AOI, a permeability of the AOI, or a concentration of the target resource in the AOI, determining a quality index (QI) for the target resource for the AOI using the one or more parameters of the AOI, and a recoverable amount (RA) of the target resource for the AOI using the recovery factor and the one or more parameters of the AOI, and identifying a highest quality region for resource recovery for the target resource as a region of interest (ROI) using the QI, the RA, and the objectives for the resource extraction.

Clause 2: The method of clause 1, further including running a static model of the AOI to determine the one or more parameters for the AOI.

Clause 3: The method of clause 1 or 2, wherein determining the quality index includes providing a QI grid corresponding to the AOI, the QI grid including a plurality of QI cells respectively corresponding to regions of the AOI, each of the plurality of QI cells in the QI grid having a respective QI value for the target resource.

Clause 4: The method of clause 3, wherein the determining the recoverable amount for the target resource includes providing an RA grid corresponding to the AOI, the RA grid including a plurality of RA cells respectively corresponding to the regions of the AOI and respectively to the plurality of QI cells, each of the plurality of RA cells in the RA grid having a respective RA value for the target resource.

Clause 5: The method of any preceding clause, wherein the one or more objectives for the resource extraction include a production target value for the target resource.

Clause 6: The method of any of clauses 1 to 4, further including determining a production target value for the target resource based on the one or more objectives for the resource extraction.

Clause 7: The method of clause 6, wherein the one or more objectives for the resource extraction include: a desired period of time for resource extraction from the AOI, and a target periodic production rate for the target resource.

Clause 8: The method of any of clauses 5 to 7, wherein the identifying a highest quality region for resource recovery for the target resource as a region of interest (ROI) includes: identifying a first QI cell having a highest QI value among the plurality of QI cells in the QI grid, identifying a first RA cell in the RA grid corresponding to the first QI cell in the QI grid, and comparing a first RA value of the first RA cell to the production target value.

Clause 9: The method of clause 8, further including, when the RA value of the first RA cell is greater than or equal to the production target value, determining that the first RA cell corresponds to the ROI.

Clause 10: The method of any of clauses 8 or 9, further including, when the RA value of the first RA cell is less than the production target value: identifying a first expanded QI region in the QI grid, the first expanded QI region including: the first QI cell, and a second QI cell in contact with the first QI cell, the second QI cell having a second-highest QI value among the plurality of QI cells in the QI grid, identifying a first expanded RA region in the RA grid, the first expanded RA region including: the first RA cell, and a second RA cell in the RA grid corresponding to the second QI cell in the QI grid, adding together the RA values for all of the cells in the first expanded RA region to determine a first expanded RA region value, and comparing the first expanded RA region value to the production target value.

Clause 11: The method of clause 10, further including, when the first expanded RA region value is greater than or equal to the production target value, determining that the first expanded RA region corresponds to the ROI.

Clause 12: The method of any of clauses 10 or 11, further including, when the first expanded RA region value is less than the production target value: repeating, until a next expanded RA region value is greater than or equal to the production target value: identifying a next expanded QI region in the QI grid, the next expanded QI region including: a most recent expanded QI region, and a next QI cell in contact with the most recent expanded QI region, the next QI cell having a next-highest QI value among the plurality of QI cells in the QI grid, identifying a next expanded RA region in the RA grid, the next expanded RA region including: a most recent expanded RA region, and a next RA cell in the RA grid corresponding to the next QI cell in the QI grid, adding together the RA values for all of the cells in the next expanded RA region to determine a next expanded RA region value, and comparing the next expanded RA region value to the production target value, and when the next expanded RA region value is greater than or equal to the production target value, determining that the next expanded RA region corresponds to the ROI.

Clause 13: The method of any of clauses 5 to 12, further including: simulating the resource extraction operation for the identified ROI to determine a respective productivity index (PI) for each cell in the ROI, determining an average PI value for the cells in the ROI, and determining an initial number of wells to be placed in the identified ROI to meet the production target value based on the average PI value when the resource extraction operation is performed in the AOI.

Clause 14: The method of clause 13, wherein the simulating the resource extraction operation includes performing a dynamic simulation on one or more notional wells for each cell to derive a brine flow rate in the one or more notional wells, the dynamic simulation using the one or more parameters of the AOI.

Clause 15: The method of clause 14, wherein the dynamic simulation applies a linear flow rate equation for each of the notional wells.

Clause 16: The method of clause 15, wherein the dynamic simulation is performed for a period shorter than 100 days.

Clause 17: The method of any preceding clause, wherein: the target resource includes a material in a brine, the QI is a brine quality index (BQI), and the BQI is expressed as:

$$BQI = Σ ( RQI \times Vc \times Sw , c \times {C}_{T} ) ,$$

where: C_{T} is a concentration of the material in the brine, Sw,c is an initial water saturation in a cell, Vc is a cell volume, and RQI is a reservoir quality index.

Clause 18: The method of clause 17, wherein: an overall reservoir quality index (RQI) is expressed by:

$$RQI = 0.0314 \sqrt{\frac{k}{ϕ}} ,$$

where: k is a permeability, and φ is a porosity.

Clause 19: The method of any of clauses 17 or 18, wherein: the target resource includes lithium, the BQI is a lithium quality index (LQI), and the LQI is expressed as:

$$LQI = Σ ( RQI \times Vc \times Sw , c \times {C}_{Li} ) ,$$

where: C_{Li} is a lithium concentration in the brine.

Clause 20: The method of any of clauses 13 to 19, wherein the determining the initial number of wells includes: determining an average target resource concentration for the cells in the ROI, multiplying the average target resource concentration by a periodic production rate, and dividing a result of the multiplying by the average PI value for the ROI.

Clause 21: The method of any preceding clause, wherein the target resource includes at least one of: lithium, oil, gas, a mineral, or a brine.

Clause 22: A method including: receiving inputs for estimating production of a target resource from a resource extraction operation in an area of interest (AOI), the inputs including one or more parameters for the AOI, including a porosity of the AOI, a permeability of the AOI, a concentration of the target resource in the AOI, one or more objectives for the resource extraction, deriving a production target value from the one or more objectives for the resource extraction, simulating the resource extraction operation in at least a region of interest (ROI) of the AOI to determine a respective productivity index (PI) for each cell in the ROI using the one or more parameters for the ROI, the simulating the resource extraction operation including performing a dynamic simulation for one or more notional wells for each cell to derive a brine flow rate in the one or more notional wells, the dynamic simulation using the one or more parameters for the ROI, determine an average PI value for the cells in the ROI, and determining an initial number of wells to be placed in the ROI to meet the production target value based on the average PI value when the resource extraction operation is performed in the AOI.

Clause 23: The method of clause 22, further including running a static model of the AOI to determine the one or more parameters for the AOI.

Clause 24: The method of any of clauses 22 or 23, wherein the one or more objectives for the resource extraction include a production target value for the target resource.

Clause 25: The method of any of clauses 22 or 23, wherein: the one or more objectives for the resource extraction include: a desired period of time for resource extraction from the AOI, and a target periodic production rate for the target resource, and the method further includes calculating the production target resource value based on the desired period of time for resource extraction from the AOI and the target periodic production rate for the target resource.

Clause 26: The method of any of clauses 22 to 25, wherein the dynamic simulation applies a linear flow rate equation for each of the notional wells.

Clause 27: The method of any of clauses 22 to 26, wherein the dynamic simulation is performed for a period shorter than 100 days.

Clause 28: The method of any of clauses 22 to 27, wherein the determining the initial number of wells includes: determining an average target resource concentration for the cells in the ROI, multiplying the average target resource concentration by a periodic production rate, and dividing a result of the multiplying by the average PI value for the ROI.

Clause 29: The method of any of clauses 22 to 28, wherein the target resource includes at least one of: lithium, oil, gas, a mineral, or a brine.

Clause 30: The method of any of clauses 22 to 29, further including mapping the productivity index for the ROI based on the average PI value.

Clause 31: The method of clause 30, further including identifying which contiguous area has a highest collective productivity index.

Clause 32: The method of clause 31, further including determining an acreage of the contiguous area used in production or costs of the production based on the objectives for the target resource extraction.

Clause 33: The method of any of clauses 22 to 32, further including: determining whether one or more rate sensitivities exist for the resource extraction, and deriving the productivity index based on the rate sensitivities.

Clause 34: The method of clause 33, wherein: the productivity index is based on a drawdown pressure, and the one or more rate sensitivities include a drawdown pressure rate sensitivity.

Clause 35: The method of any of clauses 22 to 34, further including selecting the ROI, the selecting the ROI including: determining a quality index (QI) for the target resource for the AOI using the one or more parameters of the AOI, and a recoverable amount (RA) of the target resource for the AOI using the one or more parameters of the AOI and the recovery factor, and identifying the region of interest (ROI) using the QI and the RA and the objectives for the resource extraction.

Clause 36: The method of clause 35, wherein the determining the quality index includes providing a QI grid corresponding to the AOI, the QI grid including a plurality of QI cells respectively corresponding to regions of the AOI, each of the plurality of QI cells in the QI grid having a respective QI value for the target resource.

Clause 37: The method of clause 36, wherein the determining the recoverable amount for the target resource includes providing an RA grid corresponding to the AOI, the RA grid including a plurality of RA cells respectively corresponding to the regions of the AOI and respectively to the plurality of QI cells, each of the plurality of RA cells in the RA grid having a respective RA value for the target resource.

Clause 38: The method of any of clauses 36 to 37, wherein the identifying the region of interest (ROI) includes: identifying a first QI cell having a highest QI value among the plurality of QI cells in the QI grid, identifying a first RA cell in the RA grid corresponding to the first QI cell in the QI grid, and comparing a first RA value of the first RA cell to the production target value.

Clause 39: The method of clause 38, further including, when the RA value of the first RA cell is greater than or equal to the production target value, determining that the first RA cell corresponds to the ROI.

Clause 40: The method of any of clauses 38 or 39, further including, when the RA value of the first RA cell is less than the production target value: identifying a first expanded QI region in the QI grid, the first expanded QI region including: the first QI cell, and a second QI cell in contact with the first QI cell, the second QI cell having a second-highest QI value among the plurality of QI cells in the QI grid, identifying a first expanded RA region in the RA grid, the first expanded RA region including: the first RA cell, and a second RA cell in the RA grid corresponding to the second QI cell in the QI grid, adding together the RA values for all of the cells in the first expanded RA region to determine a first expanded RA region value, and comparing the first expanded RA region value to the production target value.

Clause 41: The method of clause 40, further including, when the first expanded RA region value is greater than or equal to the production target value, determining that the first expanded RA region corresponds to the ROI.

Clause 42: The method of any of clauses 40 or 41, further including, when the first expanded RA region value is less than the production target value: repeating, until a next expanded RA region value is greater than or equal to the production target value: identifying a next expanded QI region in the QI grid, the next expanded QI region including: a most recent expanded QI region, and a next QI cell in contact with the most recent expanded QI region, the next QI cell having a next-highest QI value among the plurality of QI cells in the QI grid, identifying a next expanded RA region in the RA grid, the next expanded RA region including: a most recent expanded RA region, and a next RA cell in the RA grid corresponding to the next QI cell in the QI grid, adding together the RA values for all of the cells in the next expanded RA region to determine a next expanded RA region value, and comparing the next expanded RA region value to the production target value, and when the next expanded RA region value is greater than or equal to the production target value, determining that the next expanded RA region corresponds to the ROI.

Clause 43: The method of any of clauses 35 to 42, wherein: the target resource includes a material in a brine, the QI is a brine quality index (BQI), and the BQI is expressed as:

$$BQI = Σ ( RQI \times Vc \times Sw , c \times {C}_{T} ) ,$$

where: C_{T} is a concentration of the material in the brine, Sw,c is an initial water saturation in the cell, Vc is a cell volume, and RQI is a reservoir quality index.

Clause 44: The method of clause 43, wherein: the target resource includes lithium, the BQI is a lithium quality index (LQI), and the LQI is expressed as:

$$LQI = Σ ( RQI \times Vc \times Sw , c \times {C}_{Li} ) ,$$

where: C_{Li} is a lithium concentration in the brine.

Clause 45: The method of any of clauses 43 or 44, wherein: an overall reservoir quality index (RQI) is expressed by:

$$RQI = 0.0314 \sqrt{\frac{k}{ϕ}} ,$$

where: k is a permeability, and φ is a porosity.

Systems and software, e.g., implemented on a non-transitory computer-readable medium, for performing the methods discussed herein are also within the scope of embodiments of the present disclosure.

Embodiments of the present disclosure may thus utilize a special purpose or general-purpose computing system including computer hardware, such as, for example, one or more processors and system memory. Embodiments within the scope of the present disclosure also include physical and other computer-readable media for carrying or storing computer-executable instructions and/or data structures, including applications, tables, data, libraries, or other modules used to execute particular functions or direct selection or execution of other modules. Such computer-readable media can be any available media that can be accessed by a general purpose or special purpose computer system. Computer-readable media that store computer-executable instructions (or software instructions) are physical storage media. Computer-readable media that carry computer-executable instructions are transmission media. Thus, by way of example, and not limitation, embodiments of the present disclosure can include at least two distinctly different kinds of computer-readable media, namely physical storage media or transmission media. Combinations of physical storage media and transmission media should also be included within the scope of computer-readable media.

Both physical storage media and transmission media may be used temporarily store or carry, software instructions in the form of computer readable program code that allows performance of embodiments of the present disclosure. Physical storage media may further be used to persistently or permanently store such software instructions. Examples of physical storage media include physical memory (e.g., RAM, ROM, EPROM, EEPROM, etc.), optical disk storage (e.g., CD, DVD, HDDVD, Blu-ray, etc.), storage devices (e.g., magnetic disk storage, tape storage, diskette, etc.), flash or other solid-state storage or memory, or any other non-transmission medium which can be used to store program code in the form of computer-executable instructions or data structures and which can be accessed by a general purpose or special purpose computer, whether such program code is stored as or in software, hardware, firmware, or combinations thereof.

A “network” or “communications network” may generally be defined as one or more data links that enable the transport of electronic data between computer systems and/or modules, engines, and/or other electronic devices. When information is transferred or provided over a communication network or another communications connection (either hardwired, wireless, or a combination of hardwired or wireless) to a computing device, the computing device properly views the connection as a transmission medium. Transmission media can include a communication network and/or data links, carrier waves, wireless signals, and the like, which can be used to carry desired program or template code means or instructions in the form of computer-executable instructions or data structures and which can be accessed by a general purpose or special purpose computer.

Further, upon reaching various computer system components, program code in the form of computer-executable instructions or data structures can be transferred automatically or manually from transmission media to physical storage media (or vice versa). For example, computer-executable instructions or data structures received over a network or data link can be buffered in memory (e.g., RAM) within a network interface module (NIC), and then eventually transferred to computer system RAM and/or to less volatile physical storage media at a computer system. Thus, it should be understood that physical storage media can be included in computer system components that also (or even primarily) utilize transmission media.

One or more specific embodiments of the present disclosure are described herein. These described embodiments are examples of the presently disclosed techniques. Additionally, in an effort to provide a concise description of these embodiments, not all features of an actual embodiment may be described in the specification. It should be appreciated that in the development of any such actual implementation, as in any engineering or design project, numerous embodiment-specific decisions will be made to achieve the developers' specific goals, such as compliance with system-related and business-related constraints, which may vary from one embodiment to another. Moreover, it should be appreciated that such a development effort might be complex and time consuming, but would nevertheless be a routine undertaking of design, fabrication, and manufacture for those of ordinary skill having the benefit of this disclosure.

The articles “a,” “an,” and “the” are intended to mean that there are one or more of the elements in the preceding descriptions. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. For example, any element described in relation to an embodiment herein may be combinable with any element of any other embodiment described herein. Numbers, percentages, ratios, or other values stated herein are intended to include that value, and also other values that are “about” or “approximately” the stated value, as would be appreciated by one of ordinary skill in the art encompassed by embodiments of the present disclosure. A stated value should therefore be interpreted broadly enough to encompass values that are at least close enough to the stated value to perform a desired function or achieve a desired result. The stated values include at least the variation to be expected in a suitable manufacturing or production process, and may include values that are within 5%, within 1%, within 0.1%, or within 0.01% of a stated value.

A person having ordinary skill in the art should realize in view of the present disclosure that equivalent constructions do not depart from the spirit and scope of the present disclosure, and that various changes, substitutions, and alterations may be made to embodiments disclosed herein without departing from the spirit and scope of the present disclosure. Equivalent constructions, including functional “means-plus-function” clauses are intended to cover the structures described herein as performing the recited function, including both structural equivalents that operate in the same manner, and equivalent structures that provide the same function. It is the express intention of the applicant not to invoke means-plus-function or other functional claiming for any claim except for those in which the words ‘means for’ appear together with an associated function. Each addition, deletion, and modification to the embodiments that falls within the meaning and scope of the claims is to be embraced by the claims.

The terms “approximately,” “about,” and “substantially” as used herein represent an amount close to the stated amount that still performs a desired function or achieves a desired result. For example, the terms “approximately,” “about,” and “substantially” may refer to an amount that is within less than 5% of, within less than 1% of, within less than 0.1% of, and within less than 0.01% of a stated amount. Further, it should be understood that any directions or reference frames in the preceding description are merely relative directions or movements. For example, any references to “up” and “down” or “above” or “below” are merely descriptive of the relative position or movement of the related elements.

The present disclosure may be embodied in other specific forms without departing from its spirit or characteristics. The described embodiments are to be considered as illustrative and not restrictive. The scope of the disclosure is, therefore, indicated by the appended claims rather than by the foregoing description. Changes that come within the meaning and range of equivalency of the claims are to be embraced within their scope.

The disclosure relates to the following clauses

Clause A1. A method comprising receiving inputs for estimating production of a target resource from a resource extraction operation in an area of interest (AOI), the inputs comprising a recovery factor for the target resource in the AOI, one or more objectives for the resource extraction, and one or more parameters of the AOI, the one or more parameters of the AOI comprising one or more of: a porosity of the AOI, a permeability of the AOI, or a concentration of the target resource in the AOI; determining a quality index (QI) for the target resource for the AOI using the one or more parameters of the AOI, and a recoverable amount (RA) of the target resource for the AOI using the recovery factor and the one or more parameters of the AOI; and identifying a highest quality region for resource recovery for the target resource as a region of interest (ROI) using the QI, the RA, and the objectives for the resource extraction.

Clause A2. The method of Clause A1, further comprising running a static model of the AOI to determine the one or more parameters for the AOI.

Clause A3. The method of Clause A1 or Clause A2, wherein determining the quality index includes providing a QI grid corresponding to the AOI, the QI grid comprising a plurality of QI cells respectively corresponding to regions of the AOI, each of the plurality of QI cells in the QI grid having a respective QI value for the target resource.

Clause A4. The method of Clause A3, wherein determining the recoverable amount for the target resource comprises providing an RA grid corresponding to the AOI, the RA grid comprising a plurality of RA cells respectively corresponding to the regions of the AOI and respectively to the plurality of QI cells, each of the plurality of RA cells in the RA grid having a respective RA value for the target resource.

Clause A5. The method of any of Clauses A1 to A4, wherein the one or more objectives for the resource extraction comprise a production target value for the target resource.

Clause A6. The method of any of Clauses A1 to A4, further comprising determining a production target value for the target resource based on the one or more objectives for the resource extraction.

Clause A7. The method of Clause A6, wherein the one or more objectives for the resource extraction comprise: a desired period of time for resource extraction from the AOI; and a target periodic production rate for the target resource.

Clause A8. The method of any of Clauses A5 to A7, wherein identifying a highest quality region for resource recovery for the target resource as a region of interest (ROI) comprises: identifying a first QI cell having a highest QI value among the plurality of QI cells in the QI grid; identifying a first RA cell in the RA grid corresponding to the first QI cell in the QI grid; and comparing a first RA value of the first RA cell to the production target value.

Clause A9. The method of Clause A8, further comprising, when the RA value of the first RA cell is greater than or equal to the production target value, determining that the first RA cell corresponds to the ROI.

Clause A10. The method of any of Clauses A8 or A9, further comprising, when the RA value of the first RA cell is less than the production target value: identifying a first expanded QI region in the QI grid, the first expanded QI region including the first QI cell and a second QI cell in contact with the first QI cell, the second QI cell having a second-highest QI value among the plurality of QI cells in the QI grid; identifying a first expanded RA region in the RA grid, the first expanded RA region including the first RA cell and a second RA cell in the RA grid corresponding to the second QI cell in the QI grid; adding together the RA values for all of the cells in the first expanded RA region to determine a first expanded RA region value; and comparing the first expanded RA region value to the production target value.

Clause A11. The method of Clause A10, further comprising, when the first expanded RA region value is greater than or equal to the production target value, determining that the first expanded RA region corresponds to the ROI.

Clause A12. The method of any of Clauses A10 or A11, further comprising, when the first expanded RA region value is less than the production target value: repeating, until a next expanded RA region value is greater than or equal to the production target value: identifying a next expanded QI region in the QI grid, the next expanded QI region including the most recent expanded QI region and a next QI cell in contact with the most recent expanded QI region, the next QI cell having a next-highest QI value among the plurality of QI cells in the QI grid; identifying a next expanded RA region in the RA grid, the next expanded RA region including the most recent expanded RA region and a next RA cell in the RA grid corresponding to the next QI cell in the QI grid; adding together the RA values for all of the cells in the next expanded RA region to determine a next expanded RA region value; and comparing the next expanded RA region value to the production target value; and when the next expanded RA region value is greater than or equal to the production target value, determining that the next expanded RA region corresponds to the ROI.

Clause A13. The method of any of Clauses A5 to A12, further comprising: simulating the resource extraction operation for the identified ROI to determine a respective productivity index (PI) for each cell in the ROI; determining an average PI value for the cells in the ROI; and determining an initial number of wells to be placed in the identified ROI to meet the production target value based on the average PI value when the resource extraction operation is performed in the AOI.

Clause A14. The method of Clause A13, wherein simulating the resource extraction operation includes performing a dynamic simulation on one or more notional wells for each cell to derive a brine flow rate in the one or more notional wells, the dynamic simulation using the one or more parameters of the AOI.

Clause A15. The method of Clause A14, wherein the dynamic simulation applies a linear flow rate equation for each of the notional wells.

Clause A16. The method of Clause A15, wherein the dynamic simulation is performed for a period shorter than 100 days.

Clause A17. The method of any of Clauses A1 to A16, wherein the target resource comprises a material in a brine; the QI is a brine quality index (BQI); and BQI is expressed

$$BQI = Σ ( RQI \times Vc \times Sw , c \times {C}_{T} ) ,$$

where CT is a concentration of the material in the brine, Sw,c is an initial water saturation in a cell, Vc is a cell volume, and RQI is a reservoir quality index.

Clause A18. The method of Clause A17, wherein an overall reservoir quality index (RQI) is expressed by

$$RQI = 0.0314 \sqrt{\frac{k}{ϕ}} ,$$

where k is permeability, and φ is porosity.

Clause A19. The method of any of Clauses A17 or A18, wherein the target resource comprises lithium; the BQI is a lithium quality index (LQI); and LQI is expressed as

$$LQI = Σ ( RQI \times Vc \times Sw , c \times {C}_{Li} ) ,$$

where C_{Li} is a lithium concentration in the brine.

Clause A20. The method of any of Clauses A13 to A19, wherein determining the initial number of wells comprises: determining an average target resource concentration for the cells in the ROI; multiplying the average target resource concentration by a periodic production rate; and dividing a result of the multiplying by the average PI value for the ROI.

Clause A21. The method of any of Clauses A1 to A20, wherein the target resource comprises at least one of: lithium, oil, gas, a mineral, or a brine.

Clause B1. A method comprising receiving inputs for estimating production of a target resource from a resource extraction operation in an area of interest (AOI), the inputs comprising one or more parameters for the AOI, including a porosity of the AOI, a permeability of the AOI, a concentration of the target resource in the AOI, one or more objectives for the resource extraction; deriving a production target value from the one or more objectives for the resource extraction; simulating the resource extraction operation in at least a region of interest (ROI) of the AOI to determine a respective productivity index (PI) for each cell in the ROI using the one or more parameters for the ROI, the simulating the resource extraction operation comprising performing a dynamic simulation for one or more notional wells for each cell to derive a brine flow rate in the one or more notional wells, the dynamic simulation using the one or more parameters for the ROI; determining an average PI value for the cells in the ROI; and determining an initial number of wells to be placed in the ROI to meet the production target value based on the average PI value when the resource extraction operation is performed in the AOI.

Clause B2. The method of Clause B1, further comprising running a static model of the AOI to determine the one or more parameters for the AOI.

Clause B3. The method of Clause B1 or Clause B2, wherein the one or more objectives for the resource extraction include a production target value for the target resource.

Clause B4. The method of Clause B1 or Clause B2, wherein the one or more objectives for the resource extraction include: a desired period of time for resource extraction from the AOI; and a target periodic production rate for the target resource; and the method further comprises calculating the production target resource value based on the desired period of time for resource extraction from the AOI and the target periodic production rate for the target resource.

Clause B5. The method of any of Clauses B1 to B4, wherein the dynamic simulation applies a linear flow rate equation for each of the notional wells.

Clause B6. The method of any of Clauses B1 to B5, wherein the dynamic simulation is performed for a period shorter than 100 days.

Clause B7. The method of any of Clauses B1 to B6, wherein determining the initial number of wells comprises: determining an average target resource concentration for the cells in the ROI; multiplying the average target resource concentration by a periodic production rate; and dividing a result of the multiplying by the average PI value for the ROI.

Clause B8. The method of any of Clauses B1 to B7, wherein the target resource comprises at least one of: lithium, oil, gas, a mineral, or a brine.

Clause B9. The method of any of Clauses B1 to B8, further comprising mapping the productivity index for the ROI based on the average PI value.

Clause B10. The method of Clause B9, further comprising identifying which contiguous area has a highest collective productivity index.

Clause B11. The method of Clause B10, further comprising determining an acreage of the contiguous area used in production or costs of the production based on the objectives for the target resource extraction.

Clause B12. The method of any of Clauses B1 to B11, further comprising: determining whether one or more rate sensitivities exist for the resource extraction; and deriving the productivity index based on the rate sensitivities.

Clause B13. The method of Clause B12, wherein the productivity index is based on a drawdown pressure; and the one or more rate sensitivities include a drawdown pressure rate sensitivity.

Clause B14. The method of any of Clauses B1 to B13, further comprising selecting the ROI, the selecting including: determining a quality index (QI) for the target resource for the AOI using the one or more parameters of the AOI, and a recoverable amount (RA) of the target resource for the AOI using the one or more parameters of the AOI and the recovery factor; and identifying the ROI using the QI, the RA, and the objectives for the resource extraction.

Clause B15. The method of Clause B14, wherein determining the quality index includes providing a QI grid corresponding to the AOI, the QI grid comprising a plurality of QI cells respectively corresponding to regions of the AOI, each of the plurality of QI cells in the QI grid having a respective QI value for the target resource.

Clause B16. The method of Clause B15, wherein determining the recoverable amount for the target resource includes providing an RA grid corresponding to the AOI, the RA grid comprising a plurality of RA cells respectively corresponding to the regions of the AOI and respectively to the plurality of QI cells, each of the plurality of RA cells in the RA grid having a respective RA value for the target resource.

Clause B17. The method of any of Clauses B15 or B16, wherein identifying the ROI comprises: identifying a first QI cell having a highest QI value among the plurality of QI cells in the QI grid; identifying a first RA cell in the RA grid corresponding to the first QI cell in the QI grid; and comparing a first RA value of the first RA cell to the production target value.

Clause B18. The method of Clause B17, further comprising, when the RA value of the first RA cell is greater than or equal to the production target value, determining that the first RA cell corresponds to the ROI.

Clause B19. The method of any of Clauses B17 or B18, further comprising, when the RA value of the first RA cell is less than the production target value: identifying a first expanded QI region in the QI grid, the first expanded QI region including the first QI cell and a second QI cell in contact with the first QI cell, the second QI cell having a second-highest QI value among the plurality of QI cells in the QI grid; identifying a first expanded RA region in the RA grid, the first expanded RA region including the first RA cell and a second RA cell in the RA grid corresponding to the second QI cell in the QI grid; adding together the RA values for all of the cells in the first expanded RA region to determine a first expanded RA region value; and comparing the first expanded RA region value to the production target value.

Clause B20. The method of Clause B19, further comprising, when the first expanded RA region value is greater than or equal to the production target value, determining that the first expanded RA region corresponds to the ROI.

Clause B21. The method of any of Clauses B19 or B20, further comprising, when the first expanded RA region value is less than the production target value: repeating, until a next expanded RA region value is greater than or equal to the production target value: identifying a next expanded QI region in the QI grid, the next expanded QI region including the most recent expanded QI region and a next QI cell in contact with the most recent expanded QI region, the next QI cell having a next-highest QI value among the plurality of QI cells in the QI grid; identifying a next expanded RA region in the RA grid, the next expanded RA region including the most recent expanded RA region and a next RA cell in the RA grid corresponding to the next QI cell in the QI grid; adding together the RA values for all of the cells in the next expanded RA region to determine a next expanded RA region value; and comparing the next expanded RA region value to the production target value; and when the next expanded RA region value is greater than or equal to the production target value, determining that the next expanded RA region corresponds to the ROI.

Clause B22. The method of any of Clauses B14 to B21, wherein the target resource comprises a material in a brine; the QI is a brine quality index (BQI); and the BQI is expressed as BQI=CT·(1−Sw,c) Vc RQI, where CT is a concentration of the material in the brine, Sw,c is initial water saturation in the cell, Vc is cell volume, and RQI is reservoir quality index.

Clause B23. The method of Clause B22, wherein the target resource comprises lithium; the BQI is a lithium quality index (LQI); and the LQI is expressed as LQI=CLi·(1−Sw,c)·Vc·RQI, where CLi is a lithium concentration in the brine.

Clause B24. The method of any of Clauses B22 or B23, wherein an overall reservoir quality index (RQI) is expressed by RQI=sqrt(k/φ), where k is permeability and φ is porosity.

1. A method comprising:
receiving inputs for estimating production of a target resource from a resource extraction operation in an area of interest (AOI), the inputs comprising one or more parameters for the AOI, including a porosity of the AOI, a permeability of the AOI, a concentration of the target resource in the AOI, one or more objectives for the resource extraction,
deriving a production target value from the one or more objectives for the resource extraction,
simulating the resource extraction operation in at least a region of interest (ROI) of the AOI to determine a respective productivity index (PI) for each cell in the ROI using the one or more parameters for the ROI, the simulating the resource extraction operation comprising performing a dynamic simulation for one or more notional wells for each cell to derive a brine flow rate in the one or more notional wells, the dynamic simulation using the one or more parameters for the ROI;
determine an average PI value for the cells in the ROI; and
determining an initial number of wells to be placed in the ROI to meet the production target value based on the average PI value when the resource extraction operation is performed in the AOI.

2. The method of claim 1, further comprising running a static model of the AOI to determine the one or more parameters for the AOI.

3. The method of claim 1, wherein the one or more objectives for the resource extraction include or are in relationship to a production target value for the target resource.

4. The method of claim 3, wherein:
the one or more objectives for the resource extraction include:
a desired period of time for resource extraction from the AOI; and
a target periodic production rate for the target resource; and
the method further comprises calculating the production target resource value based on the desired period of time for resource extraction from the AOI and the target periodic production rate for the target resource.

5. The method of claim 1, wherein the dynamic simulation applies a linear flow rate equation for each of the notional wells.

6. The method of claim 1, wherein the determining the initial number of wells comprises:
determining an average target resource concentration for the cells in the ROI;
multiplying the average target resource concentration by a periodic production rate; and
dividing a result of the multiplying by the average PI value for the ROI.

7. The method of claim 1, further comprising:
mapping the productivity index for the ROI based on the average PI value
identifying which contiguous area has a highest collective productivity index, and
determining an acreage of the contiguous area used in production or costs of the
production based on the objectives for the target resource extraction.

8. The method of claim 1, further comprising:
determining whether one or more rate sensitivities exist for the resource extraction; and
deriving the productivity index based on the rate sensitivities.

9. The method of claim 8, wherein:
the productivity index is based on a drawdown pressure; and
the one or more rate sensitivities include a drawdown pressure rate sensitivity.

10. The method of claim 1, further comprising selecting the ROI, the selecting the ROI including:
determining a quality index (QI) for the target resource for the AOI using the one or more parameters of the AOI, and a recoverable amount (RA) of the target resource for the AOI using the one or more parameters of the AOI and the recovery factor; and
identifying the region of interest (ROI) using the QI and the RA and the objectives for the resource extraction.

11. A method, comprising:
receiving inputs for estimating production of a target resource from a resource extraction operation in an area of interest (AOI), the inputs comprising a recovery factor for the target resource in the AOI, one or more objectives for the resource extraction, and one or more parameters of the AOI, the one or more parameters of the AOI comprising one or more of: a porosity of the AOI, a permeability of the AOI, or a concentration of the target resource in the AOI;
determining a quality index (QI) for the target resource for the AOI using the one or more parameters of the AOI, and a recoverable amount (RA) of the target resource for the AOI using the recovery factor and the one or more parameters of the AOI; and
identifying a highest quality region for resource recovery for the target resource as a region of interest (ROI) using the QI, the RA, and the objectives for the resource extraction.

12. The method of claim 11, further comprising running a static model of the AOI to determine the one or more parameters for the AOI.

13. The method of claim 11, wherein the one or more objectives for the resource extraction comprise or are in relationship to a production target value for the target resource.

14. The method of claim 13, wherein the one or more objectives for the resource extraction comprise:
a desired period of time for resource extraction from the AOI; and
a target periodic production rate for the target resource.
further comprising determining a production target value for the target resource based on the one or more objectives for the resource extraction.

15. The method of claim 13,
wherein determining the quality index includes providing a QI grid corresponding to the AOI, the QI grid including a plurality of QI cells respectively corresponding to regions of the AOI, each of the plurality of QI cells in the QI grid having a respective QI value for the target resource,
wherein the determining the recoverable amount for the target resource includes providing an RA grid corresponding to the AOI, the RA grid including a plurality of RA cells respectively corresponding to the regions of the AOI and respectively to the plurality of QI cells, each of the plurality of RA cells in the RA grid having a respective RA value for the target resource.
wherein the identifying a highest quality region for resource recovery for the target resource as a region of interest (ROI) comprises:
identifying a first QI cell having a highest QI value among the plurality of QI cells in the QI grid;
identifying a first RA cell in the RA grid corresponding to the first QI cell in the QI grid; and
comparing a first RA value of the first RA cell to the production target value.

16. The method of claim 15, further comprising, when the RA value of the first RA cell is less than the production target value:
identifying a first expanded QI region in the QI grid, the first expanded QI region including:
the first QI cell; and
a second QI cell in contact with the first QI cell, the second QI cell having a second-highest QI value among the plurality of QI cells in the QI grid;
identifying a first expanded RA region in the RA grid, the first expanded RA region including:
the first RA cell; and
a second RA cell in the RA grid corresponding to the second QI cell in the QI grid;
adding together the RA values for all of the cells in the first expanded RA region to determine a first expanded RA region value; and
comparing the first expanded RA region value to the production target value.

17. The method of claim 16, further comprising, when the first expanded RA region value is less than the production target value:
repeating, until a next expanded RA region value is greater than or equal to the production target value:
identifying a next expanded QI region in the QI grid, the next expanded QI region including:
a most recent expanded QI region; and
a next QI cell in contact with the most recent expanded QI region, the next QI cell having a next-highest QI value among the plurality of QI cells in the QI grid;
identifying a next expanded RA region in the RA grid, the next expanded RA region including:
a most recent expanded RA region; and
a next RA cell in the RA grid corresponding to the next QI cell in the QI grid;
adding together the RA values for all of the cells in the next expanded RA region to determine a next expanded RA region value; and
comparing the next expanded RA region value to the production target value; and
when the next expanded RA region value is greater than or equal to the production target value, determining that the next expanded RA region corresponds to the ROI.

18. The method of claim 11, further comprising:
simulating the resource extraction operation for the identified ROI to determine a respective productivity index (PI) for each cell in the ROI;
determining an average PI value for the cells in the ROI; and
determining an initial number of wells to be placed in the identified ROI to meet the production target value based on the average PI value when the resource extraction operation is performed in the AOI.

19. The method of claim 18, wherein the simulating the resource extraction operation includes performing a dynamic simulation on one or more notional wells for each cell to derive a brine flow rate in the one or more notional wells, the dynamic simulation using the one or more parameters of the AOI, wherein the dynamic simulation applies a linear flow rate equation for each of the notional wells.

20. The method of claim 11, wherein:
the target resource comprises a material in a brine;
the QI is a brine quality index (BQI); and
the BQI is expressed as:
$$BQI = Σ ( RQI \times Vc \times Sw , c \times {C}_{T} ) ,$$
where:
C_{T} is a concentration of the material in the brine,
Sw,c is an initial water saturation in the cell,
Vc is a cell volume, and
RQI is a reservoir quality index.
